(19) United States
(12) Patent Application Publication
(10) Pub. No.: US 2026/0009874 A1
(43) Pub. Date: Jan. 8, 2026

(54) TRANSMISSION CABLE ASSEMBLY AND INTERFERENCE SIGNAL SUPPRESSION METHOD FOR TRANSMISSION CABLE ASSEMBLY

(71) Applicant: SHANGHAI UNITED IMAGING HEALTHCARE CO., LTD., Shanghai (CN)

(72) Inventors: Baifan HUANG, Shanghai (CN); Bing GUO, Shanghai (CN); Junjun QIN, Shanghai (CN)

(73) Assignee: SHANGHAI UNITED IMAGING HEALTHCARE CO., LTD., Shanghai (CN)

(21) Appl. No.: 19/324,208

(22) Filed: Sep. 10, 2025

Related U.S. Application Data
(63) Continuation-in-part of application No. 18/826,175, filed on Sep. 6, 2024.

(30) Foreign Application Priority Data
Oct. 26, 2023 (CN) 202311404553.9
Jan. 19, 2024 (CN) 202420136619.4
Sep. 19, 2024 (CN) 202422293013.4
Oct. 15, 2024 (CN) 202422497492.1

(51) Int. Cl. G01R 33/36

(52) U.S. Cl. CPC G01R 33/3685; G01R 33/3642

(57) ABSTRACT

The present disclosure provides a transmission cable assembly for an RF coil, comprising: a transmission cable electrically connected to the RF coil; an outer sheath sleeved over the transmission cable; a plurality of traps and one or more insulating components arranged between the transmission cable and the outer sheath, wherein: the plurality of traps are sleeved over the transmission cable and spaced apart along a longitudinal axis of the transmission cable, each of one or more insulating components is placed between two adjacent traps of the plurality of traps.

### CROSS-REFERENCE

This application claims priority to Chinese Application No. 202422293013.4, filed Sep. 19, 2024 and Chinese Application No. 202422497492.1, filed Oct. 15, 2024, and is a continuation-in-part of U.S. Ser. No. 18/826,175, filed on Sep. 6, 2024, which claims priority to Chinese Application No. 202311404553.9, filed Oct. 26, 2023 and Chinese Application No. 202420136619.4, filed Jan. 19, 2024, the contents of each of which is incorporated by reference into this application in its entirety.

### TECHNICAL FIELD

This invention relates to the field of medical equipment technology, particularly regarding transmission cable assemblies and methods for suppressing interference signals in the transmission cable assembly.

### BACKGROUND

Medical professionals can use Magnetic Resonance Imaging (MRI) systems to non-invasively obtain images of arbitrary cross-sections of the human body to assist their diagnosis. During an MRI scan, the volume transmit coil (VTC) emits power, causing significant common-mode currents in the transmission cables. The common-mode currents may cause interference to the local radiofrequency field (known as the B1 field), thus compromising image quality. To suppress or reduce these common-mode currents, traps can be installed on the cables. However, as imaging technology continues to advance, the number of elements in the MRI receiving coils increases, resulting in thicker transmission cables. The increased size of the transmission cable poses greater challenges for the design of RF traps.

One category of conventional traps, known as cable traps, is constructed by winding the transmission cable into a spiral shape, and then enclosing it with a shielding cover. One end of the shielding cover is directly soldered to the transmission cable, while the other end is connected to the transmission cable via a tuning capacitor. Because cable traps typically have a large inductance, they can effectively suppress common-mode currents while generating minimal heat. However, a cable trap has several drawbacks, such as its volume is typically large and weight is heavy, and it increases the internal RF line losses and impacts the total phase distance. Additionally, as the transmission cable becomes thicker, the diameter of the spiral windings also increases, leading to even larger and heavier traps. The drawbacks of the cable trap thus compound and become unacceptable.

Another category of conventional traps, known as floating traps, do not need to be connected to the transmission cable. They can be fitted onto and removed from the transmission cable. However, the floating trap typically has a small inductance and generates a significant amount of heat. Its performance to reduce common-mode currents relies on the size of its diameter—the larger the diameter, the better the performance. Therefore, in order to effectively suppress common-mode currents, the floating trap has to be large and thus inevitably heavy.

Embodiments of the disclosure address the above drawbacks of existing traps and provide transmission cable assemblies with improved traps that are smaller and lighter while maintaining a good performance in suppressing common-mode currents.

### SUMMARY

One or more embodiments of the present disclosure provide a transmission cable assembly for a radio frequency (RF) coil, comprising: a transmission cable electrically connected to the RF coil; an outer sheath sleeved over the transmission cable; a plurality of traps and one or more insulating components arranged between the transmission cable and the outer sheath, wherein: the plurality of traps are sleeved over the transmission cable and spaced apart along a longitudinal axis of the transmission cable, each of one or more insulating components is placed between two adjacent traps of the plurality of traps.

In some embodiments, the outer sheath is made of a flexible material.

In some embodiments, the one or more insulating components are made of a flexible material.

In some embodiments, an outer diameter of each trap is the same as an outer diameter of each insulating component such that the transmission cable assembly has a uniform outer diameter.

In some embodiments, the plurality of traps comprise a first trap, and the first trap comprises: an inner sleeve sleeved over the transmission cable; an outer sleeve sleeved over the inner sleeve; and one or more first discrete capacitors electrically connected between the inner sleeve and the outer sleeve.

In some embodiments, the first trap further comprises a circuit board having a ring structure, an inner ring of the circuit board is connected to the inner sleeve, an outer ring of the circuit board is connected to the outer sleeve; and the one or more first discrete capacitors are disposed on the circuit board.

In some embodiments, a plurality of holes are arranged on the outer sleeve, the plurality of holes are divided into a plurality of hole groups, each of which comprises holes distributed along a circumferential direction of the outer sleeve, the hole groups are spaced apart along a longitudinal axis of the outer sleeve, and the holes in adjacent hole groups are arranged staggerly.

In some embodiments, the plurality of traps comprise a second trap comprising: a first coil, both ends of the first coil being disconnected to form a first gap; a second coil, both ends of the second coil being disconnected to form a second gap; one or more second discrete capacitors, each of which is electrically connected to the first coil or the second coil.

In some embodiments, the transmission cable assembly further comprises: a bracket sleeved over the transmission cable, wherein the first coil and the second coil are wound around an outer surface of the bracket, and the bracket is provided with a mounting hole; and an inductance tuning component inserted into the mounting hole and configured to adjust a resonance frequency of the first coil and the second coil, wherein the resonance frequency of the first coil and the second coil is adjusted by adjusting an insertion depth of the inductance tuning component relative to the mounting hole.

In some embodiments, the first coil and the second coil are configured based on one or more coil parameters, the one or more coil parameters are determined by optimizing one or more initial coil parameters to achieve an optimization target, the optimization target is related to a Q factor of the first coil and the second coil.

In some embodiments, the transmission cable assembly further comprises a connector, wherein the connector comprises: a connecting component coupled to an end of the transmission cable; and a housing sleeved over the connecting component.

In some embodiments, the transmission cable comprises a signal transmission line and a tensile strength line; the connecting component forms a second channel for the signal transmission line and the tensile strength line to pass through, and the connecting component comprises a positioning line connected to the tensile strength line.

In some embodiments, the transmission cable is divided into a first cable segment and a second cable segment, the second cable segment being further away from a central region of a volume transmit coil of a magnetic resonance imaging (MRI) device than the first cable segment, a first portion of the plurality of traps are sleeved over the first cable segment, a second portion of the plurality of traps are sleeved over the second cable segment, and an arrangement density of the second portion of the plurality of traps is higher than that of the first portion of the plurality of traps.

In some embodiments, the transmission cable is divided into a first cable segment and a second cable segment, the second cable segment being further away from a central region of a volume transmit coil of an MRI device than the first cable segment, the plurality of traps comprise first traps and second traps, each first trap comprising two sleeves and one or more first discrete capacitors, each second trap comprising two coils and one or more second discrete capacitors, the first traps are sleeved over the first cable segment, and the second traps are sleeved over the second cable segment.

One or more embodiments of the present disclosure provide a magnetic resonance imaging (MRI) device, comprising: a RF coil configured to detect MRI signals; a supporting table configured to support an object to be scanned; a coil plug disposed on the supporting table; and a transmission cable assembly connect the RF coil and the coil plug, the transmission cable assembly comprising a transmission cable, a plurality of traps and one or more insulating components, wherein the plurality of traps are sleeved over the transmission cable and spaced apart along a longitudinal axis of the transmission cable, each of one or more insulating components is placed between two adjacent traps of the plurality of traps, and the transmission cable assembly assumes a uniform shape.

In some embodiments, the MRI device further includes a mattress the mattress is provided with one or more accommodation grooves extending along a longitudinal direction of the mattress, the one or more accommodation grooves are configured to accommodate the transmission cable assembly, each accommodation groove comprises one or more first grooves and one or more second grooves connected to each other, and along a width direction of the mattress, a dimension of each second groove is greater than a dimension of each first groove.

In some embodiments, the one or more second grooves comprise a plurality of second grooves, and adjacent second grooves are spaced apart along the longitudinal direction by one of the one or more first grooves.

In some embodiments, an opening of each second groove has an oblong shape or a rectangular shape, and at least a portion of a cross-section of each first groove is semicircular.

In some embodiments, the mattress comprises a supporting portion and two accommodation portions, the two accommodation portions are respectively connected to two sides of the supporting portion along the width direction of the mattress, and the one or more accommodation grooves comprise two accommodation grooves disposed on the two accommodation portions, respectively.

In some embodiments, the mattress is assembled by connecting a plurality of mattress segments along the length direction of the mattress, the mattress segments comprise one or more first mattress segments and one or more second mattress segments, only a portion of the one or more first grooves are arranged on the one or more first mattress segments, the one or more second grooves and the remaining portion of the one or more first grooves are arranged on the one or more second mattress segments.

### BRIEF DESCRIPTION OF THE DRAWINGS

The present disclosure may be further described in terms of exemplary embodiments, which may be described in detail with reference to the drawings. These embodiments are not limiting, and in these embodiments, the same reference numerals in the various drawings represent similar structures, and where:

FIG. 1 shows an equivalent circuit diagram of an exemplary transmission cable assembly according to embodiments of the present disclosure.

FIG. 2 shows an equivalent circuit diagram of an exemplary transmission cable assembly according to embodiments of the present disclosure.

FIG. 3 is a schematic diagram showing a front view of a transmission cable assembly with a closed-loop spiral coil trap and a transmission cable inserted therein, according to embodiments of the present disclosure.

FIG. 4 is a schematic diagram showing an isometric view of a transmission cable assembly with a closed-loop spiral coil trap and a transmission cable inserted therein, according to embodiments of the present disclosure.

FIG. 5 is a schematic diagram showing a front view of a transmission cable assembly with an open-loop spiral coil trap and a transmission cable inserted therein, according to embodiments of the present disclosure.

FIG. 6 is a schematic diagram showing an open-loop spiral coil, according to embodiments of the present disclosure.

FIG. 7 is a schematic diagram showing an isometric view of a transmission cable assembly with a closed-loop spiral coil trap and a transmission cable inserted therein, according to embodiments of the present disclosure.

FIG. 8 is a schematic diagram showing an isometric view of a transmission cable assembly with an open-loop spiral coil trap fitted to a transmission cable and a shielding enclosure around the spiral coil trap, according to embodiments of the present disclosure.

FIG. 9 is a schematic diagram showing a closed-loop spiral coil trap wound around a bracket, according to embodiments of the present disclosure.

FIG. 10 is a schematic diagram showing a closed-loop spiral coil trap wound around a bracket with a transmission cable inserted in a through hole of the bracket, according to embodiments of the present disclosure.

FIG. 11 is a schematic diagram showing a transmission cable assembly with an open-loop spiral coil trap wound around a bracket and a transmission cable inserted therein, according to embodiments of the present disclosure.

FIG. 12 is a schematic diagram showing a perspective view of a transmission cable assembly with a trap composed of a first printed circuit board (PCB), a second printed circuit board (PCB), and a third printed circuit board (PCB), and a transmission cable inserted therein, according to embodiments of the present disclosure.

FIG. 13 is a schematic diagram showing a perspective view of a first printed circuit board (PCB) in a trap, according to embodiments of the present disclosure.

FIG. 14 is a schematic diagram showing a front surface of the first PCB of FIG. 13, according to embodiments of the present disclosure.

FIG. 15 is a schematic diagram showing a back surface of the first PCB of FIG. 13, according to embodiments of the present disclosure.

FIG. 16 is a schematic diagram showing a perspective view of a second printed circuit board (PCB) in a trap, according to embodiments of the present disclosure.

FIG. 17 is a schematic diagram showing a perspective view of a third printed circuit board (PCB) in a trap, according to embodiments of the present disclosure.

FIG. 18 is a schematic diagram showing a transmission cable assembly with multiple closed-loop spiral coil traps fitted on a transmission cable, according to embodiments of the present disclosure.

FIG. 19 is a schematic diagram showing a transmission cable assembly with multiple open-loop spiral coil traps fitted on a transmission cable, according to embodiments of the present disclosure.

FIG. 20 is a schematic diagram showing a transmission cable assembly with multiple closed-loop spiral coil traps wound around respective brackets fitted on a transmission cable, according to embodiments of the present disclosure.

FIG. 21 is a schematic diagram showing a transmission cable assembly with multiple open-loop spiral coil traps wound around respective brackets fitted on a transmission cable, according to embodiments of the present disclosure.

FIG. 22 is a schematic diagram showing a transmission cable assembly with multiple PCB traps fitted on a transmission cable, according to embodiments of the present disclosure.

FIG. 23 shows an equivalent circuit diagram of an exemplary transmission cable assembly having multiple closed-loop traps, according to embodiments of the present disclosure.

FIG. 24 shows an equivalent circuit diagram of another exemplary trap assembly having multiple open-loop traps, according to embodiments of the present disclosure.

FIG. 25 is a schematic diagram of a trap fitted on a transmission cable according to embodiments of the present disclosure.

FIG. 26 is a perspective diagram of a trap fitted on a transmission cable according to embodiments of the present disclosure.

FIG. 27 shows a trap with multiple gaps according to embodiments of the present disclosure.

FIG. 28 shows a trap with discrete capacitors disposed on gaps according to embodiments of the present disclosure.

FIG. 29 is a schematic diagram showing a trap with twisted pair structure, according to embodiments of the present disclosure.

FIG. 30 is a schematic diagram showing a trap with a shielding enclosure according to embodiments of the present disclosure.

FIG. 31 is a schematic diagram showing multiple traps fitted on a transmission cable with a bracket according to embodiments of the present disclosure.

FIG. 32 shows an equivalent circuit diagram of the multiple traps in FIG. 31 according to embodiments of the present disclosure.

FIG. 33 is a schematic diagram showing a conventional trap according to some embodiments of the present disclosure.

FIG. 34 is a schematic diagram showing an MRI system according to some embodiments of the present disclosure.

FIG. 35 is a schematic diagram showing a transmission cable assembly according to some embodiments of the present disclosure.

FIG. 36 is a schematic diagram showing a first trap according to some embodiments of the present disclosure.

FIG. 37 is a schematic diagram showing a first trap sleeved over a transmission cable according to some embodiments of the present disclosure.

FIG. 38 is a schematic diagram showing a plurality of first traps sleeved over a transmission cable according to some embodiments of the present disclosure.

FIG. 39 is a schematic diagram showing an outer sleeve according to some embodiments of the present disclosure.

FIG. 40 is a schematic diagram showing a side view of an outer sleeve according to some embodiments of the present disclosure.

FIG. 41 is a schematic diagram showing a second trap according to some embodiments of the present disclosure.

FIG. 42 is a schematic diagram showing a transmission cable assembly according to some embodiments of the present disclosure.

FIG. 43 is a schematic diagram showing an internal structure of a connector according to some embodiments of the present disclosure.

FIG. 44 is a schematic diagram showing an assembled connector according to some embodiments of the present disclosure.

FIG. 45 is a schematic diagram showing a mattress of an MRI device according to some embodiments of the present disclosure.

FIG. 46 is a schematic diagram showing a top view of a mattress of an MRI device according to some embodiments of the present disclosure.

FIG. 47 is a schematic diagram showing a side view of a mattress of an MRI device according to some embodiments of the present disclosure.

FIG. 48 is a schematic diagram showing a side view of a mattress of an MRI device according to some embodiments of the present disclosure.

FIG. 49 is a schematic diagram showing a side view of a mattress of an MRI device with a transmission cable assembly installed according to some embodiments of the present disclosure.

### DETAILED DESCRIPTION

In order to more clearly illustrate the technical solutions of the embodiments of the present disclosure, the accompanying drawings required to be used in the description of the embodiments will be briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. The present disclosure can be applied to other similar scenarios based on these drawings without creative labor. Unless obviously obtained from the context or the context illustrates otherwise, the same numeral in the drawings refers to the same structure or operation.

It should be understood that the terms “system,” “device,” as used herein, “unit,” and/or “module” as used herein is a way to distinguish between different components, elements, parts, sections or assemblies at different levels. However, said words may be replaced by other expressions if other words accomplish the same purpose.

As shown in the disclosure and claims, unless the context clearly indicates an exception, words such as “one,” “a,” “an,” and/or “the” do not specifically refer to the singular, but may also include the plural. Generally, the terms “including,” and “comprising” suggest only the inclusion of clearly identified steps and elements. In general, the terms “including,” and “comprising” only suggest the inclusion of explicitly identified steps and elements that do not constitute an exclusive list, and the method or device may also include other steps or elements.

Flowcharts are used in this disclosure to illustrate operations performed by a system according to embodiments of this disclosure. It should be appreciated that the preceding or following operations are not necessarily performed in an exact sequence. Instead, steps can be processed in reverse order or simultaneously. Also, it is possible to add other operations to these processes or remove a step or steps from them.

In the field of imaging technology, Magnetic resonance imaging (MRI), which utilizes the phenomenon of magnetic resonance to image an object, has been a common medical imaging detection method. During the imaging process using a magnetic resonance device, the effects of factors such as involuntary movement and physiological activity of the object may result in motion artifacts in the image, which may affect the image-based diagnosis and research.

Traditional Gradient Recalled Echo (GRE) sequence techniques can be combined with physiological triggering techniques to suppress motion artifacts. One combination is to perform unsteady-state GRE K-space data acquisition directly after a physiological trigger point, and the other combination is to set a reasonable number of dummy scans before the physiological trigger point, so that the GRE signal reaches the steady-state before the K-space data acquisition.

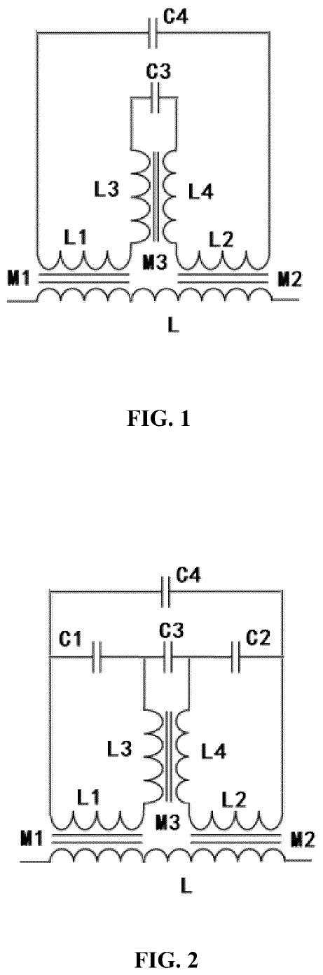

When the at least two coils include a first coil and a second coil and the at least one trap includes a single trap, an equivalent circuit diagram is shown in FIG. 1. As used herein, a trap including two coils is also referred to as a second trap. L denotes an equivalent inductor of the transmission cable, L1 denotes an equivalent inductor of the first coil, L2 denotes an equivalent inductor of the second coil, L3 and L4 denote inductors formed by coupling between the first coil and the second coil, C3 and C4 denote distributed capacitors between the first coil and the second coil, M1 denotes a mutual inductance between the first coil and the transmission cable, M2 denotes a mutual inductance between the second coil and the transmission cable, and M3 denotes a mutual inductance between the first coil and the second coil. In some embodiments, the inductors L1, L2, L3, and L4 and the distributed capacitors C3 and C4 form the resonant circuit.

In some embodiments, adjusting the number of spiral turns or changing the relative positions of the first coil and the second coil influences the equivalent circuit's inductance values (L1, L2, L3, and L4) and/or the distributed capacitances (C3 and C4). Adjusting the number of turns or the positions allows for resonance and the suppression of common-mode currents.

In some current scenarios, the trap only includes a single coil, in order to reduce the common-mode currents on the transmission cable, the current of the single coil is large, causing the overheat of the single coil. By setting multiple coils included in the trap according to the present disclosure, currents can be distributed/dispersed in the multiple coils, reducing the heat generated in each individual coil of the multiple coils.

Besides, fitting the disclosed trap to the transmission cable without direct electrical connections improves maintainability. The disclosed trap skips the need to wind the transmission cable itself. Accordingly, the volume of the trap is no longer limited by the thickness of the transmission cable, allowing them to be smaller and lighter. The design can reduce the size and weight of the trap, while achieving the desired common-current reduction effects.

In some embodiments, a count of the at least one trap may be multiple, that is, multiple traps are (evenly) provided on the transmission cable along a longitudinal axis of the transmission cable. An insulating component may be placed between two adjacent traps, preventing short circuits between the traps. In some embodiments, the insulating component may be made of an insulating material, such as air, plastic, rubber, glass, ceramics, epoxy resin, etc. The insulation properties between the adjacent two traps may be different due to different insulating dielectric of different insulating materials.

The serial arrangement may provide enhanced common-mode current suppression capabilities and results in low heat generation, and thus are suitable for different types of transmission cables. The serial traps can be easily installed on and completely detached from any transmission cable without affecting any coil parameters, making it convenient for manufacturing and debugging. This also disperses the energy across multiple traps, reducing the heat generated by individual traps. Even if a specific trap is damaged, it will not affect the overall effectiveness of common-mode current suppression. In some embodiments, the multiple traps may be evenly distributed along the transmission cable, further enhancing the effectiveness of suppressing common-mode currents in the transmission cable.

In some embodiments, the resonance and/or the suppression of common-mode currents may be adjusted by adjusting one or more parameters of the at least two coils, setting one or more gaps, setting one or more additional components, or the like, or any combination thereof. The parameter(s) include a winding direction of the at least two coils, a length of a coil, a diameter of the coil, number of turns of the coil, a space between the at least two coils, etc. The one or more additional component(s) include a tuning capacitor, a twisted pair structure, etc. In some embodiments, the tuning capacitor includes an additional capacitor disposed on the coil, e.g., a lumped capacitor.

When the at least two coils include a first coil and a second coil, the at least one trap includes a single trap, and the first coil and the second coil each includes an additional tuning capacitor, an equivalent circuit diagram is shown in FIG. 2. L denotes an equivalent inductor of the transmission cable, L1 denotes an equivalent inductor of the first coil, L2 denotes an equivalent inductor of the second coil, L3 and L4 denotes inductors formed by coupling between the first coil and the second coil, C3 and C4 denotes distributed capacitors between the first coil and the second coil, M1 denotes a mutual inductance between the first coil and the transmission cable, M2 denotes a mutual inductance between the second coil and the transmission cable, M3 denotes a mutual inductance between the first coil and the second coil, C1 denotes a tuning capacitor of the first coil, C2 denotes a tuning capacitor of the second coil. In some embodiments, the inductors L1, L2, L3, and L4 and the capacitors C1, C2, C3, and C4 form a resonant circuit (e.g., a parallel resonant circuit).

In some embodiments, adjusting the capacitance values of C1 and C2 allows for resonance. Accordingly, the first coil and the second coil collectively form an equivalent circuit that can function as a resonant circuit to suppress common-mode currents in the transmission cable. As a result, the trap can effectively eliminate or reduce the impact of the common-mode currents on the local RF (B1) field. The external signal interference with the RF coil reception signals during transmission is thereby reduced.

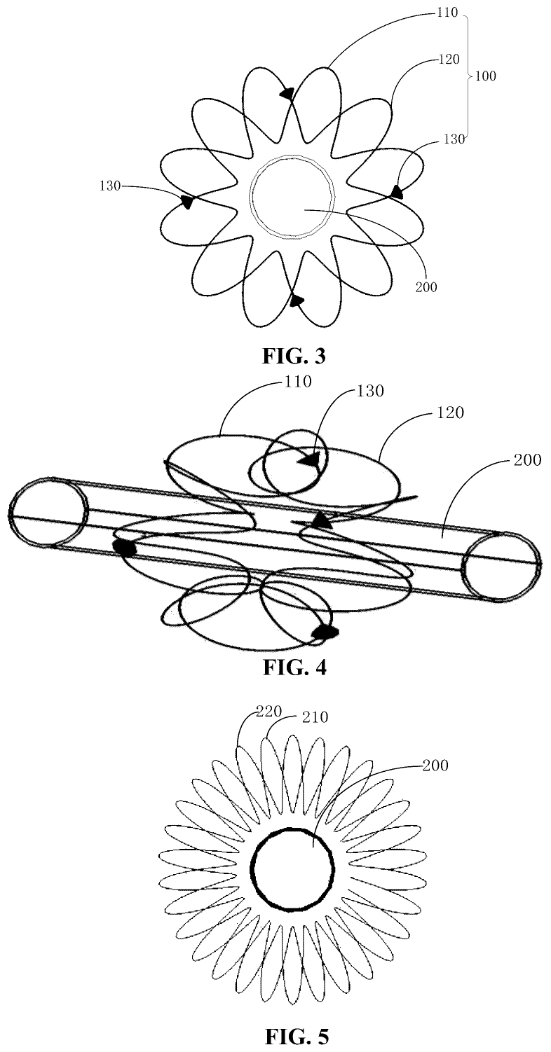

Since the capacitance value of the capacitor formed by the gap is usually smaller than the capacitance value of the lumped capacitor, the size of the trap with the lumped capacitor can be smaller than the size of the trap with the gap (e.g., as shown in FIGS. 3 and 5), by achieving the same effect.

In some embodiments, the at least two coils may be wound in different winding directions (design 1) or in the same winding direction (design 2). Since the amount of magnetic field generated in design 1 is larger than the amount of magnetic field generated in design 2, by achieving the same effect, the size of the trap including the at least two coils in different winding directions may be much smaller than the size of the trap including the at least two coils in the same winding direction.

In some embodiments, the at least two coils may circumferentially surround at least a portion of the transmission cable. In some embodiments, the transmission cable includes multiple portions along the longitude direction of the transmission cable. For example, the at least a portion of the transmission cable may include one portion of the multiple portions of the transmission cable. In some embodiments, a trap is fitted onto each of at least one portion of the multiple portions of the transmission cable.

The winding direction of one (e.g., each) of the at least two coils is a clockwise direction or the winding direction of the coil is an anticlockwise direction. When the coil is wound in the clockwise direction, it means that each turn of the coil is wound in the clockwise direction, and multiple turns of the coil are (spirally) distributed along a circumferential direction of the at least a portion of the transmission cable (e.g., as shown in FIG. 4). When the coil is wound in the anticlockwise direction, it means that each turn of the coil is wound in the anticlockwise direction, and multiple turns of the coil is (spirally) distributed along a circumferential direction of the at least a portion of the transmission cable (e.g., as shown in FIG. 4). “Clockwise direction” used herein means that: if the coil starts at the top of the transmission cable (the 12 o'clock position on a clock), it moves to the right (towards the 3 o'clock position), then down (towards the 6 o'clock position), then to the left (towards the 9 o'clock position), and finally back up towards the starting point at the top (12 o'clock position). “Anticlockwise direction” used herein means that: if the coil starts at the top of the transmission cable (the 12 o'clock position on a clock), it moves to the left (towards the 9 o'clock position), then down (towards the 6 o'clock position), then to the right (towards the 3 o'clock position), and finally back up towards the starting point at the top (12 o'clock position).

In some embodiments, the at least two coils may be wound into a shape such that the coils effectively form inductances. For example, the shape may include a spiral shape (e.g., a rosette spiral shape) with multiple spiral turns, an elliptic shape with multiple elliptic turns, a square shape with multiple square turns, etc.

In some embodiments, the at least two coils may be made of a conductive material.

In some embodiments, the at least two coils may be assembled to allow the transmission cable to insert through. For example, the transmission cable may be inserted into a center through hole of the trap and the trap may then be detachably fixed to transmission cable.

In some embodiments, the transmission cable can be either a direct current transmission cable or an alternating current transmission cable. In some embodiments, the transmission cable may be an RF (radiofrequency) transmission cable used for transmitting RF coil reception signals during MRI scans. It is contemplated that transmission cable can be used in other signal transmission applications, beyond transmitting RF signals in the MRI setting. The transmission cable assemblies and traps described in this application can be used with any transmission cable without limitation on ultimate use of that transmission cable.

In some embodiments, the at least two coils may be directly wound around the transmission cable, that is, no other component is between the at least two coils and the transmission cable.

In some embodiments, at least one bracket may be arranged to support the at least two coils. The at least two coils may be wound around the at least one bracket. In some embodiments, the outer peripheral surface of the at least one bracket may include at least two limiting grooves, which extend spirally along the circumferential axis of at least one bracket. The at least two limiting grooves may allow the at least two coils to be positioned inside the at least two limiting grooves, respectively. By having these limiting grooves, the at least two coils may be guided and supported by the at least one bracket, ensuring stability and facilitating the winding process. In some embodiments, the limiting grooves are unnecessary, the at least two coils are directly wound around the at least one bracket.

In some embodiments, a shape of a cross-section of the bracket is non-limiting only if the at least one bracket is able to support the at least two coils. For example, the cross-section of the bracket has a circular ring shape, an elliptic shape, a quadrangular shape, a trapezoid shape, or other regular/irregular shapes. In some embodiments, the at least one bracket is made of an insulating material.

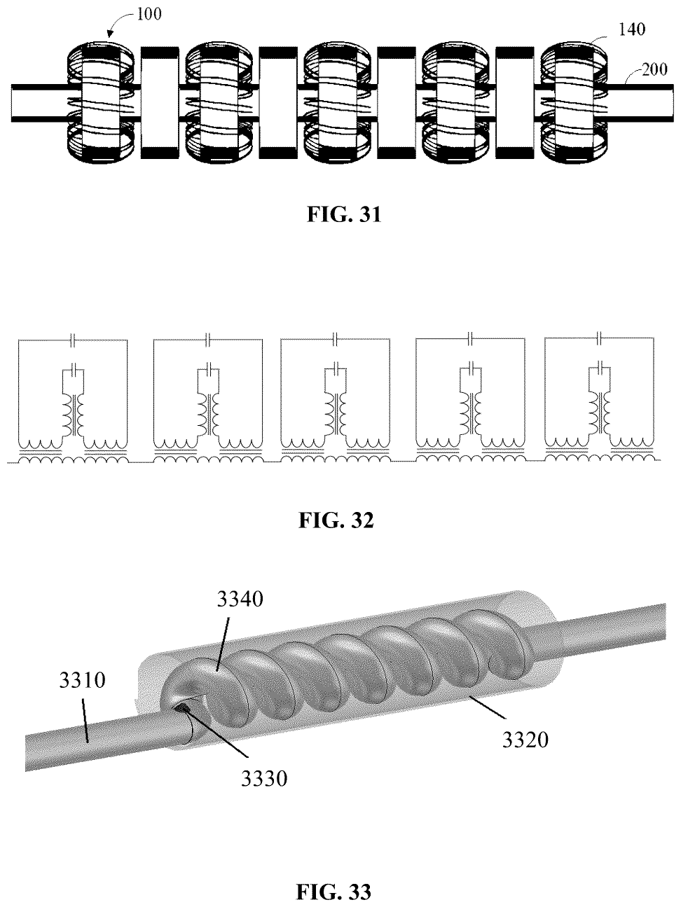

In some embodiments, to further reduce the impact of the magnetic field leaking from the coils (e.g., on the RF field), a shielding enclosure may be placed outside the at least one trap (e.g., as shown in FIG. 8, FIG. 31). The shielding enclosure may have a shielding effect, shielding the magnetic field generated by the at least one trap. In some embodiments, the shielding enclosure may cover the at least one trap. In some embodiments, a shape of a cross-section of the shielding enclosure is non-limiting only if the shielding enclosure is able to cover the at least one trap. For example, the cross-section of the shielding enclosure may have a circular ring shape, an elliptic shape, a quadrangular shape, a trapezoid shape, or other regular/irregular shapes. In some embodiments, the shielding enclosure may be made of copper, aluminum, silver, etc. An insulating medium may be filled between the shielding enclosure and the at least one trap for insulation and fixation.

In the case of the existence of multiple traps, each trap may be covered with a shielding enclosure or at least two traps may be covered with a same shielding enclosure. For example, a long shielding enclosure may be used to cover all of the multiple traps 100 simultaneously.

In some embodiments, the at least two coils in the trap can be implemented in various different ways. In some embodiments, the at least two coils can be implemented using printed circuit boards (PCBs).

In some embodiments, a gap of a coil may be formed when two ends of the coil are disconnected. When a coil has at least one gap, the coil may be denoted as an open-loop coil; when the coil has no gap, the coil may be denoted as a closed-loop coil. In some embodiments, the trap(s) and the transmission cable may be collectively denoted as a transmission cable assembly.

In some embodiments, a count of the coils may be non-limiting, for example, 2, 3, 4, or more than 4. For illustration purpose, below the at least two coils including two coils (e.g., a first coil and a second coil) will be illustrated in detail as an example.

Some embodiments of the present disclosure may describe at least one trap used to suppress interference signals on a transmission cable. The at least one trap may be fitted on (e.g., detachably fitted on) the transmission cable. Each trap may include a first coil and a second coil in different winding directions and assembled to allow the transmission cable to insert through. The first coil and the second coil may form a resonant circuit for reducing common-mode currents on the transmission cable. When there are multiple traps fitted on the transmission cable, they are spaced apart along the longitudinal axis of the transmission cable and an insulating component may be placed between every two adjacent traps. For example, the insulating component may be made of insulating material, such as plastic, resin, glass, rubber, etc.

In some embodiments, the transmission cable may be RF transmission cable used for transmitting RF coil reception signals during MRI scans, and the at least one trap may be denoted as RF trap(s) used to suppress interference signals on the transmission cable, thus reducing the impact on the local radiofrequency (B1) field.

In some embodiments, the first coil and the second coil may circumferentially surround at least a portion of the transmission cable. In some embodiments, the transmission cable includes multiple portions along the longitude direction of the transmission cable. For example, the at least a portion of the transmission cable may include one portion of the multiple portions of the transmission cable. In some embodiments, a trap is fitted onto each of at least one portion of the multiple portions of the transmission cable.

The first coil and the second coil may be in different winding directions. The different winding directions may include opposite winding directions (e.g., opposite helical directions), i.e., the clockwise direction and the anticlockwise direction. When a coil is wound in the clockwise direction, it means that each turn of the coil is wound in the clockwise direction, and multiple turns of the coil are (spirally) distributed along a circumferential direction of the at least a portion of the transmission cable (e.g., as shown in FIG. 4). When a coil is wound in the anticlockwise direction, it means that each turn of the coil is wound in the anticlockwise direction, and multiple turns of the coil are (spirally) distributed along a circumferential direction of the at least a portion of the transmission cable (e.g., as shown in FIG. 4).

In some embodiments, two coils are wound in opposite winding directions, and the two coils are also referred to as two counter-wound wires.

In some embodiments, the at least two coils included in the trap are parallel wires wound in a spiral and circumferentially wrap around at least a portion of the transmission cable. For example, the trap includes two coils, and the two coils are parallel.

The effectiveness of the disclosed traps including the opposite winding directions can be explained from two perspectives.

From an electromagnetic field perspective, the first coil and the second coil are both constructed as spiral loops but with opposite helical directions. When common-mode currents are generated on the transmission cable, the first coil and the second coil generate magnetic fields in the same direction within them. These magnetic fields inside the first coil and the second coil add up, producing currents opposite to the common-mode currents along the axial direction of the cable, thus countering the common-mode currents in the transmission cable. On the other hand, due to the opposite helical directions of the two coils, the current directions on the first coil and the second coil are also opposite. As a result, the magnetic fields outside the first coil and the second coil cancel each other out, thus reducing the impact on the local RF (B1) field. Further, placing the first coil and the second coil in overlapping positions allows them to form mutual inductance, distributing the energy coupled from the transmission cable to the traps into two current paths, effectively reducing heat.

From a circuit perspective, winding the first coil and the second coil each in a spiral loop shape can form a (parallel) resonant circuit with inductors connected in parallel with tuning capacitors. Such an equivalent circuit creates a high impedance. When the trap is placed on the transmission cable, the high impedance is applied to the transmission cable via coupling, hindering the passage of common-mode currents through the transmission cable. The mutual inductance between the first coil and the second coil reduces the overall equivalent inductance, thus reducing heat generation.

FIG. 3 is a schematic diagram showing a front view of a transmission cable assembly with a closed-loop spiral coil trap 100 and a transmission cable 200 inserted therein, according to embodiments of the present disclosure. FIG. 4 is a schematic diagram showing an isometric view of a transmission cable assembly according to embodiments of the present disclosure. FIGS. 3 and 4 will be described together.

As shown in FIG. 3 and FIG. 4, the transmission cable assembly consists of a transmission cable 200 and a trap 100 (also referred to as a second trap 100) fitted onto transmission cable 200.

Trap 100 may be detachably fitted to transmission cable 200. In some embodiments, transmission cable 200 may be inserted into a center through hole of trap 100 and trap 100 may be then detachably fixed to transmission cable 200 through a fixing means. In one embodiment, as shown in FIGS. 3 and 4, trap 100 may include a first coil 110 and a second coil 120 in opposite winding directions, that is, first coil 110 and second coil 120 are designed as two counter-wound wires. First coil 110 and second coil 120 are wound in a spiral and wrap around transmission cable 200. In some embodiments, first coil 110 and second coil 120 may both be closed-loop spiral coils, as shown in FIGS. 3 and 4. First coil 110 and second coil 120 may be wound into shapes such that the coils effectively form inductances. As shown in FIG. 3, in some embodiments, first coil 110 and second coil 120 may both be helically wound in a rosette spiral shape with multiple spiral turns.

Consistent with the disclosure, first coil 110 and second coil 120 may have opposite helical directions. First coil 110 and second coil 120 may be assembled to collectively form trap 100, which can be fitted onto transmission cable 200. The size of first coil 110 and second coil 120 may be adjusted according to the diameter of transmission cable 200 so that the coils are snuggly fitted to transmission cable 200.

In some embodiments, first coil 110 and second coil 120 may each include at least one tuning capacitor 130. The quantity of tuning capacitors used on first coil 110 and second coil 120 can vary, such as one, two, three, or more, depending on the actual application. As shown in the example of FIGS. 3 and 4, each coil is coupled with two tuning capacitors 130.

First coil 110 and second coil 120 function as inductors that, in parallel with tuning capacitors 130, create a high impedance. When trap 100 is fitted onto transmission cable 200, this high impedance is coupled to transmission cable 200, hindering the passage of common-mode currents in transmission cable 200 when it is placed in an electromagnetic field. By adjusting the capacitance value of tuning capacitor 130, resonance is achieved between first coil 110 and second coil 120, which helps to suppress common-mode currents. In some embodiments, a lumped capacitance may be used as tuning capacitor 130, and it is connected to both first coil 110 and second coil 120.

In some embodiments, the transmission cable assembly of FIGS. 3 and 4 can be used to perform an interference signal suppression method. The method includes connecting at least one tuning capacitor 130 to either first coil 110 or second coil 120 and then adjusting capacitance of tuning capacitor 130 to form a resonant circuit with first coil 110, second coil 120, and tuning capacitor 130. This resonant circuit is used to suppress interference from external signals on the RF reception signal during transmission. In some embodiments, an equivalent circuit diagram of the transmission cable assembly of FIGS. 3 and 4 is shown and illustrated in FIG. 2 above, which is not repeated herein.

In some embodiments, the transmission cable 200 may be an RF transmission cable used for transmitting RF coil reception signals during MRI scans. The opposite helical directions of first coil 110 and second coil 120 cause them to generate magnetic fields in the same direction along the circumferential distribution within transmission cable 200 when common-mode currents are present. Since their helical directions are opposite, the currents induced on first coil 110 and second coil 120 cancel each other's magnetic fields externally, reducing their impact on the local RF (B1) field. Internally, the magnetic fields generated by first coil 110 and second coil 120 add up, creating a current along the axis of transmission cable 200 opposite to the direction of the common-mode currents, effectively suppressing or reducing the currents.

In some embodiments, to minimize the size of trap 100 and its weight, first coil 110 and second coil 120 are placed one above the other to form an assembly that creates a mutual inductance. In some embodiments, first coil 110 and second coil 120 may both be helically wound in a rosette spiral shape, and the coils are assembled such that spiral turns of first coil 110 interleave with spiral turns of second coil 120. The mutual inductance allows the energy coupled from transmission cable 200 into trap 100 to be distributed into two current paths, reducing heat dissipation from the trap to the cable and resulting in a smaller and lighter trap.

In some embodiments, first coil 110 and second coil 120 include at least one gap, that is, first coil 110 and second coil 120 may both be constructed as open-loop coils (e.g., open-loop spiral coils), and capacitors are formed in gaps. For example, FIG. 5 is a schematic diagram showing a front view of a transmission cable assembly with an open-loop spiral coil trap and a transmission cable inserted therein, according to embodiments of the present disclosure.

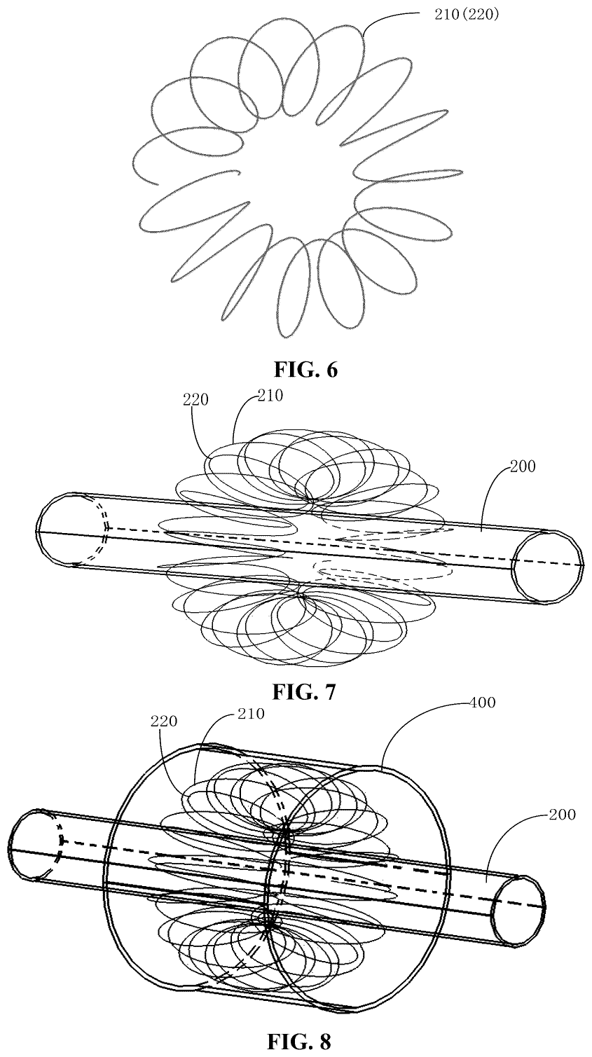

In some embodiments, as shown in FIG. 5, the transmission cable assembly may consist of transmission cable 200 and a trap fitted onto transmission cable 200. The trap may include a first coil 210 and a second coil 220. First coil 210 and second coil 220 may be each helically wound into a spiral loop with ends disconnected, forming an open-loop spiral coil. For example, FIG. 6 is a schematic diagram showing an open-loop spiral coil 210 or 220, according to embodiments of the present disclosure. As shown in FIG. 6, the two ends of the spiral coil are disconnected. Similar to first coil 110 and second coil 120 in FIGS. 3 and 4, first coil 210 and second coil 220 may be wound into shapes such that the coils effectively form inductances, such as a rosette spiral shape with multiple spiral turns, as shown in FIGS. 5 and 6.

Consistent with the disclosure, first coil 210 and the second coil 220 may have opposite helical directions. First coil 210 and second coil 220 may be assembled to collectively form trap 100. When first coil 210 and second coil 220 are assembled, distributed capacitance will form between the two coils

The size of first coil 210 and second coil 220 may be adjusted according to the diameter of transmission cable 200 so that the coils are snuggly fitted to transmission cable 200 to form the transmission cable assembly. FIG. 7 is a schematic diagram showing an isometric view of the transmission cable assembly of FIG. 5, according to embodiments of the present disclosure. In this assembly, first coil 210 and second coil 220 collectively form an equivalent circuit that can function as a resonant circuit to suppress common-mode currents in transmission cable 200.

In some embodiments, the transmission cable assembly of FIGS. 5-7 can be used to perform an interference signal suppression method. The method may include adjusting the number of spiral turns in first coil 210 or second coil 220, the length of the first coil 210 or the second coil 220, the position of the gap of first coil 210 or second coil 220, or a count of the gap of first coil 210 or second coil 220, thus creating a resonant circuit formed by the coils. This resonant circuit can be used to suppress common-mode currents induced by external signals during transmission.

In some embodiments, to further reduce the impact of the magnetic field leaking from the coils on the RF field, a shielding enclosure may be placed outside the trap. For example, FIG. 8 is a schematic diagram showing an isometric view of a transmission cable assembly with the open-loop spiral coil trap fitted to the transmission cable and a shielding enclosure 400 around the spiral coil trap, according to embodiments of the present disclosure. In some embodiments, shielding enclosure 400 may be made of copper foil. Placing shielding enclosure 400 outside the trap helps minimize the effect on the local RF (B1) field.

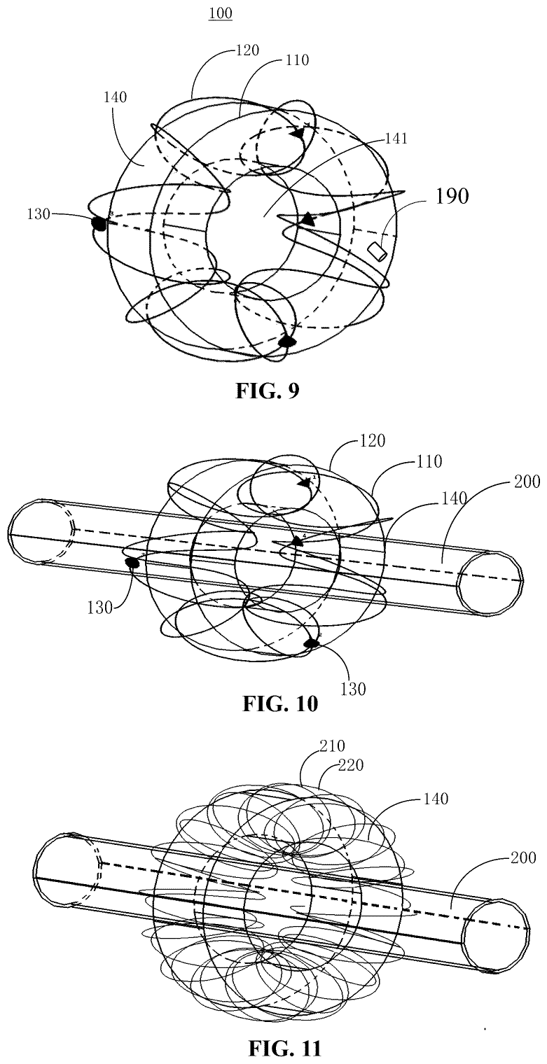

In some embodiments, the trap may further include a bracket to support the first coil and second coil and allow the transmission cable to pass through the trap. For example, FIG. 9 is a schematic diagram showing a closed-loop spiral coil trap 100 wound around a bracket 140, according to embodiments of the present disclosure. As shown in FIG. 9, trap 100 includes bracket 140 as a support frame to first coil 110 and second coil 120. Bracket 140 includes a through hole 141 in the center to allow transmission cable 200 to be inserted and pass through. First coil 110 and second coil 120 are wound around bracket 140, ensuring their stability on transmission cable 200.

In some embodiments, bracket 140 is designed to have a circular ring shape, and first coil 110 and second coil 120 are helically wound around the outer surface of bracket 140. First coil 110 and second coil 120 may each be wounded around bracket 140 into a closed loop. For example, FIG. 10 is a schematic diagram showing a closed-loop spiral coil trap wound around a bracket with a transmission cable inserted in a through hole of the bracket, according to embodiments of the present disclosure. Both first coil 110 and second coil 120 include tuning capacitors 130, and are wound around bracket 140 to form trap 100. In some embodiments, the two coils may be wound in a way to overlap with each other in order to form inductances for common-mode current suppression. Transmission cable 200 is inserted in through hole 141 in the center of bracket 140.

In some alternative embodiments, first coil and second coil may each be wounded around bracket 140 into an open loop, with disconnected ends. For example, FIG. 11 is a schematic diagram showing a transmission cable assembly with an open-loop spiral coil trap wound around a bracket and a transmission cable inserted therein, according to embodiments of the present disclosure. First coil 210 and second coil 220 do not include any tuning capacitor, but instead, are wound around bracket 140 to form capacitances between them. Transmission cable 200 is then inserted in through hole 141 in the center of bracket 140.

In some embodiments, the outer peripheral surface of bracket 140 may include first and second limiting grooves (see FIGS. 10-17), which extend spirally along the circumferential axis of bracket 140. These grooves have opposite helical directions, allowing first coil 110 (or 210) to be positioned inside the first limiting groove and second coil 120 (or 220) inside the second limiting groove. By having these limiting grooves, the first coil and the second coil are guided and supported by bracket 140, ensuring stability and facilitating the winding process.

In some embodiments, the limiting grooves can have a square shape or a U-shape. In such shapes, the depth of the first limiting groove can be greater than the diameter of the first coil, and the depth of the second limiting groove can be greater than the diameter of the second coil. This design prevents the coils from making direct contact with transmission cable 200 when the trap is fitted onto it by inserting transmission cable 200 through bracket 140, thus preventing short circuits and ensuring the reliability of the trap.

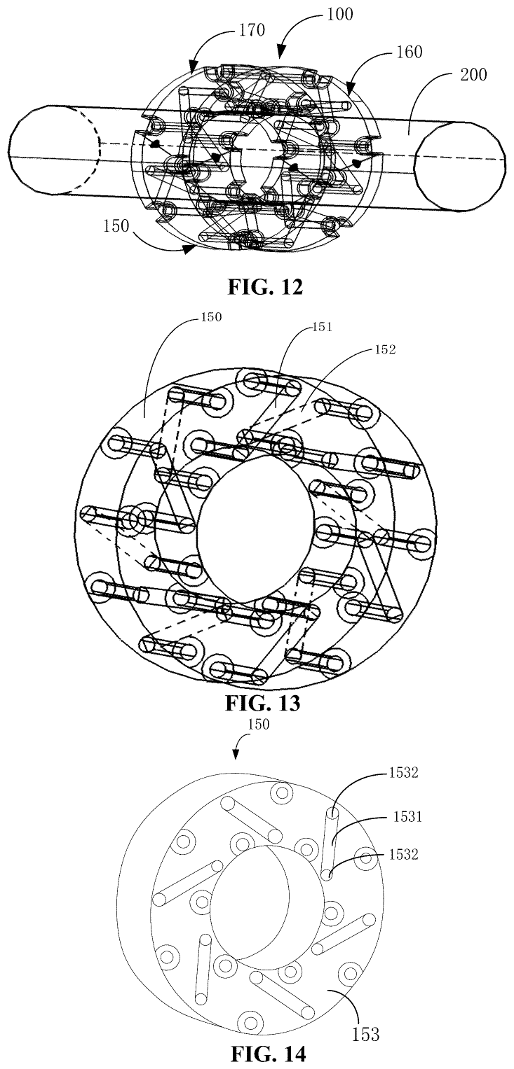

While FIGS. 3-11 show embodiments of trap 100 that includes helically wound loop coils, the first coil and second coil in the trap can be implemented in various different ways. In some embodiments, these two coils can be implemented using printed circuit boards (PCBs). For example, the two coils may be implemented with three PCBs stacked to form a trap assembly, as will be described in connection with FIGS. 12-17. In those exemplary embodiments, the first coil may be implemented using a first PCB and a second PCB, and the second coil may be implemented using the first PCB and a third PCB. The second PCB may be located on one side of the first PCB. The third PCB may be located on the other side of the first PCB. The first PCB, the second PCB, and the third PCB may each have a through hole to allow the transmission cable to insert through.

In some embodiments, the first PCB includes multiple first wires (first conducting wires) and multiple second wires (second conducting wires). The second PCB includes multiple third wires, and each of the multiple third wires (third conducting wires) is electrically connected end-to-end with one of the first wires to form the first coil. The third PCB includes multiple fourth wires (fourth conducting wires), and each of the multiple fourth wires is electrically connected end-to-end with one of the second wires to form the second coil.

In some embodiments, at least one of the first wires, the second wires, the third wires, or the fourth wires is disposed inside wire grooves of the first printed circuit board, the second printed circuit board, or the third printed circuit board, respectively. In some embodiments, the wire grooves are unnecessary, and at least one of the first wires, the second wires, the third wires, or the fourth wires is printed on surfaces of the first printed circuit board, the second printed circuit board, or the third printed circuit board, respectively.

In some embodiments, the first PCB includes a first side and a second side. The first side has multiple first wire grooves and the second side has multiple second wire grooves. The first wire grooves and the second wire grooves are distributed circumferentially along the through hole. Each first wire groove has two ends each connected to a first through hole extending through to the second side. Each second wire groove has two ends, each connected to a second through hole extending through to the first side. The first wires are located within the first wire grooves, with their two ends passing through the first through holes. The second wires are located within the second wire grooves, with their two ends passing through the second through holes. In some embodiments, the two ends of the first wires are flush with the second side. In some embodiments, the two ends of the second wires are flush with the first side.

In some embodiments, the adjacent first wires are not parallel or the adjacent first wire grooves are not parallel. For example, the adjacent first wires intersect in extension directions or the adjacent first wire grooves intersect in extension directions. In some embodiments, the adjacent second wires are not parallel or the adjacent second wire grooves are not parallel. For example, the adjacent second wires intersect in extension directions or the adjacent second wire grooves intersect in extension directions.

In some embodiments, the adjacent first wires and the adjacent third wires have opposite tilting directions or the first wire grooves and third wire grooves have opposite tilting directions. “Opposite tilting directions” used herein means that first wires or first wire grooves tilt in one direction (e.g., left) and third wires or third wire grooves tilt in an opposite direction (e.g., right).

In some embodiments, one side of the third printed circuit board includes multiple fourth wire grooves distributed circumferentially along the through hole. Each fourth wire groove has two ends each connected to fourth through hole extending through to the other side of the third printed circuit board. The fourth wires are located within the fourth wire grooves, with their two ends extending through the fourth through holes and electrically connected to two ends of the second wires.

In some embodiments, the adjacent fourth wires are not parallel or the adjacent fourth wire grooves are not parallel. The adjacent fourth wires intersect in extension directions or the adjacent fourth wire grooves intersect in extension directions.

In some embodiments, the second wires and the fourth wires have opposite tilting directions or the second wire grooves and fourth wire grooves have opposite tilting directions. “Opposite tilting directions” used herein means that second wires or second wire grooves tilt in one direction (e.g., left) and fourth wires or fourth wire grooves tilt in an opposite direction (e.g., right).

FIG. 12 is a schematic diagram showing a perspective view of a transmission cable assembly with a trap 100 composed of a first printed circuit board (PCB) 150, a second printed circuit board (PCB) 160, and a third printed circuit board (PCB) 170, and a transmission cable 200 inserted therein, according to embodiments of the present disclosure. As shown in FIG. 12, first PCB 150, second PCB 160, and third PCB 170 are stacked to form trap 100, with first PCB positioned in the middle, second PCB 160 located on one side of first PCB 150, and third PCB 170 located on the other side of the first PCB 150. In some embodiments, first PCB 150, second PCB 160, and third PCB 170 may each be a ring-shaped disk with a through hole in the center so that transmission cable 200 can be inserted through the assembly. In some embodiments, first PCB 150, second PCB 160, and third PCB 170 may have same outer diameters (diameters of the disks) and inner diameters (diameters of the through holes).

In some embodiments, first PCB 150 may have multiple first conducting wires and second conducting wires arranged in different helical directions. Second PCB 160 may have multiple third conducting wires that are electrically connected end-to-end with the first conducting wires of first PCB 150 to form first coil 110. Third PCB 170 may have multiple fourth conducting wires that are electrically connected end-to-end with the second conducting wires of first PCB 150 to form second coil 120.

By arranging second PCB 160 and third PCB 170 on opposite sides of first PCB 150 and having conducting wires wound in opposite helical directions, the size and weight of trap 100 can be reduced. This arrangement also allows the formed first coil 110 and second coil 120 to be independent of each other, enhancing the performance of the trap in suppressing common-mode currents.

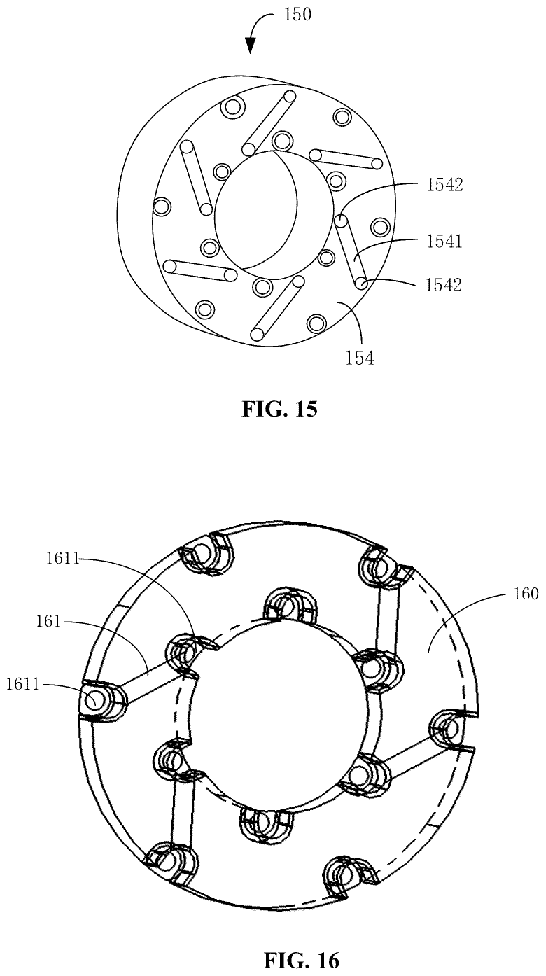

FIG. 13 is a schematic diagram showing a perspective view of a first printed circuit board (PCB) 150 in a trap, according to embodiments of the present disclosure. FIG. 14 is a schematic diagram showing a front surface of the first PCB of FIG. 13, according to embodiments of the present disclosure. FIG. 15 is a schematic diagram showing a back surface of the first PCB of FIG. 13, according to embodiments of the present disclosure. FIGS. 13-15 will be described together.

As shown in FIGS. 13-15, first PCB 150 may be a ring-shaped disk with a through hole in the center so that the transmission cable can be inserted through. In some embodiments, first PCB 150 may have multiple first conducting wires 151 and multiple second conducting wires 152. First printed circuit board 150 may include two opposing sides: a first side 153 (the side shown in FIG. 14) and a second side 154 (the side shown in FIG. 15). First conducting wires 151 may be arranged on first side 153 and second conducting wires 152 may be arranged on second side 154. In some embodiments, first conducting wires 151 and second conducting wires 152 may have opposite helical directions.

In some embodiments, as shown in FIGS. 14 and 15, there may be multiple first wire grooves 1531 provided on first side 153 and multiple second wire grooves 1541 provided on second side 154. These first wire grooves and second wire grooves may be spaced circumferentially along the through hole. It is contemplated that first PCB 150 may include more or fewer first wire grooves 1531 and second wire grooves 1541 as shown in FIGS. 13-15. Each first wire groove 1531 has two ends, each end configured with a first wiring through-hole 1532 extending to second side 154. Similarly, each second wire groove 1541 also has two ends, each end configured with a second wiring through-hole 1542 extending to first side 153. In some embodiments, the grooves can be square-shaped grooves or U-shaped grooves. It is contemplated that the shape and size of first wire grooves 1531 and second wire grooves 1541 are not limited to specific designs.

Consistent with some embodiments, each first conducting wire 151 may be placed inside a first wire groove 1531, and the two ends of first conducting wire 151 pass through first through-holes 1532. In some embodiments, the two ends of first conducting wires 151 are flush with second side 154. Similarly, each second conducting wire 152 may be placed inside a second wire groove 1541, and the two ends of second conducting wire 152 pass through second through-holes 1542. In some embodiments, the two ends of second conducting wires 152 are flush with first side 153. In some embodiments, directions of the adjacent first wire grooves 1531 are not parallel. For example, the adjacent first wire grooves 1531 are arranged to intersect in their extension directions. That is, the direction in which a first wire groove 1531 extends is not parallel with the direction in which its neighboring first wire groove 1531. Similarly, directions of the adjacent second wire grooves 1541 are not parallel. For example, the adjacent second wire grooves 1541 also intersect in their extension directions. In addition, as shown in FIGS. 14-15, first wire grooves 1531 and second wire grooves 1541 have opposite tilting directions.

By including multiple first wire grooves 1531 and second wire grooves 1541 on first side 153 and second side 154 of first PCB 150, it becomes easier to accommodate the first conducting wires 151 and second conducting wires 152. Furthermore, by providing first through-holes 1532 at the ends of the first wire grooves 1531 that extend through first PCB 150, it allows the two ends of first conducting wires 151 to pass through to second side 154, making it convenient to electrically connect the ends of first conducting wires 151 to two different conducting wires of the second PCB that will be described later. Similarly, by providing second through-holes 1542 at the ends of second wire grooves 1541 that extend through first PCB 150, it allows the two ends of the second conducting wires 152 to pass through to first side 153, making it convenient to electrically connect the ends of the second conducting wires 152 to two different conducting wires of the third PCB that will be described later.

The intersecting extension directions of adjacent first wire grooves 1531 allows first conducting wires 151 placed inside first wire grooves 1531 to form a shape of a wound coil after being electrically connected to the third conducting wires of second PCB 160. Similarly, intersecting extension directions of adjacent second wire grooves 1541 allows second conducting wires 152 placed inside second wire grooves 1541 to form a shape of a wound coil after being electrically connected to the fourth conducting wires of third PCB 170. In some embodiments, directions of first wire grooves 1531 and second wire grooves 1541 are non-limiting only if first coil 110 and second coil 120 are able to have opposite helical directions. In some embodiments, the first wire grooves 1531 and second wire grooves 1541 have opposite tilting directions.

In some embodiments, first PCB 150 is a ring-shaped disk, and first through-holes 1532 at the ends of first wire grooves 1531 and second through-holes 1542 at the ends of second wire grooves 1541 are positioned on the inner and outer walls of the first PCB 150 near first side 153 and second side 154, respectively. This allows the ends of first conducting wires 151 and second conducting wires 152 to be securely fixed to first PCB 150. In some embodiments, the depth of first wire grooves 1531 and second wire grooves 1541 is greater than the diameter of first conducting wires 151 and second conducting wires 152, ensuring that the ends of the first conducting wires 151 and second conducting wires 152 do not protrude from first wire grooves 1531 and second wire grooves 1541. This enables second PCB 160 and third PCB 170 to fit snugly against first side 153 and second side 154 of first PCB 150, resulting in a more compact structure and a smaller overall size for trap 100.

FIG. 16 is a schematic diagram showing a perspective view of a second printed circuit board (PCB) 160 in a trap, according to embodiments of the present disclosure. As shown in FIG. 16, like first PCB 150, second PCB 160 may also be a ring-shaped disk with a through hole in the center so that the transmission cable can be inserted through. In some embodiments, unlike first wire grooves 1531 and second wire grooves 1541 on the sides of first PCB 150, second PCB 160 has multiple circumferentially spaced third wire grooves 161 along the through-hole. In some embodiments, each third wire groove 161 has two ends, each end with a third through-hole 1611 that extends through to the side of second PCB 160 facing the first printed circuit board 150. In some embodiments, the extension directions of adjacent third wire grooves 161 intersect.

Third conducting wires may be placed inside third wire grooves 161. The two ends of the third conducting wires pass through the third through-holes 1611. In some embodiments, the two ends of the third conducting wires are flush with the other side of second PCB 160. The two ends of the third conducting wires are electrically connected to the ends of corresponding first conducting wires 151 located near the third conducting wires, forming first coil 110. In some embodiments, the tilting directions of first wire grooves 1531 and third wire grooves 161 are opposite. The opposite tilting directions of first wire grooves 1531 and third wire grooves 161 allow first conducting wires 151 of first PCB 150 and the third conducting wires of second PCB 160 to form a spiral coil after connection.

In some embodiments, the depth of third wire grooves 161 is greater than the diameter of the third conducting wires to ensure that the third conducting wires do not protrude from third wire grooves 161. In some embodiments, the two ends of first conducting wires 151 and the third conducting wires are connected by soldering. The positions of third through-holes 1611 located at both ends of third wire grooves 161 correspond to the positions of first through-holes 1532 adjacent to first wire grooves 1531 on first PCB 150. This alignment allows the ends of the third conducting wires within third through-holes 1611 to be properly connected with the ends of first conducting wires 151 inside the first through-holes, facilitating the soldering process. In some embodiments, third through-holes 1611 may be located between the inner and outer walls of second PCB 160. In some alternative embodiments, third through-holes 1611 can be notches that are recessed from the inner wall towards the outer wall of second PCB 160, or vice versa. This configuration allows the ends of the third conducting wires to protrude from second PCB 160, facilitating the soldering process.

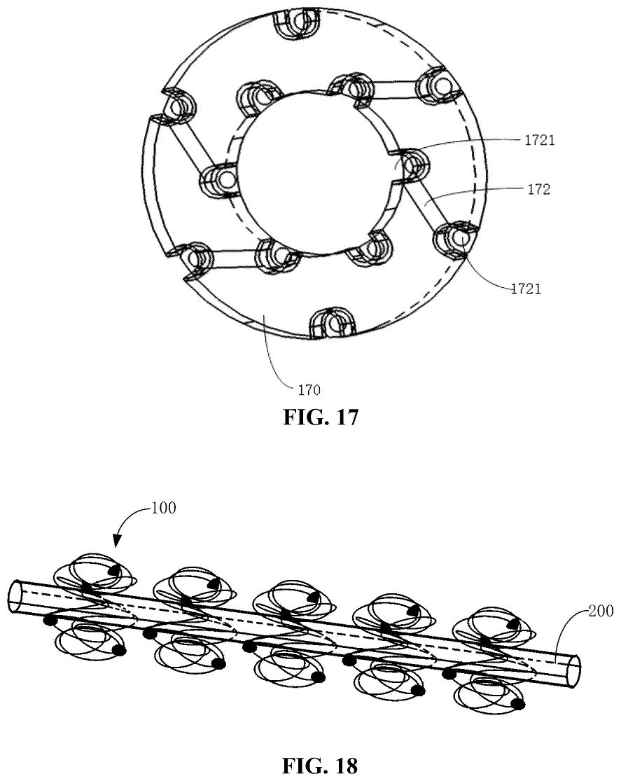

FIG. 17 is a schematic diagram showing a perspective view of a third printed circuit board (PCB) 170 in a trap, according to embodiments of the present disclosure. In some embodiments, third PCB 170 may be in a similar construction as second PCB 160, except it is stacked to first PCB 150 on the opposite side. As shown in FIG. 17, like second PCB 160, third PCB 170 may also be a ring-shaped disk with a through hole in the center so that the transmission cable can be inserted through. In some embodiments, like second PCB 160, third PCB 170 also has multiple circumferentially spaced fourth wire grooves 172 along the through-hole. In some embodiments, each fourth wire groove 172 has two ends, each end with a fourth through-hole 1721 that extends through to the side of third PCB 170 facing the first printed circuit board 150. In some embodiments, the extension directions of adjacent fourth wire grooves 172 intersect.

Fourth conducting wires may be placed inside fourth wire grooves 172. The two ends of the fourth conducting wires pass through the fourth through-holes 1721. In some embodiments, the two ends of the fourth conducting wires are flush with the other side of third PCB 170. The two ends of the fourth conducting wires are electrically connected to the ends of corresponding second conducting wires 152 located near the fourth conducting wires, forming second coil 120. In some embodiments, the tilting directions of second wire grooves 1541 and fourth wire grooves 172 are opposite. The opposite tilting directions of second wire grooves 1541 and fourth wire grooves 172 allow second conducting wires 152 of first PCB 150 and the fourth conducting wires of third PCB 170 to form a spiral coil after connection.

In some embodiments, the depth of fourth wire grooves 172 is greater than the diameter of the fourth conducting wires to ensure that the fourth conducting wires do not protrude from fourth wire grooves 172. In some embodiments, the two ends of second conducting wires 152 and the fourth conducting wires are connected by soldering. The positions of fourth through-holes 1721 located at both ends of fourth wire grooves 172 correspond to the positions of second through-holes 1542 adjacent to second wire grooves 1541 on second PCB 160. This alignment allows the ends of the fourth conducting wires within fourth through-holes 1721 to be properly connected with the ends of second conducting wires 152 inside the second through-holes, facilitating the soldering process. In some embodiments, fourth through-holes 1721 may be located between the inner and outer walls of third PCB 170. In some alternative embodiments, fourth through-holes 1721 can be notches that are recessed from the inner wall towards the outer wall of third PCB 170, or vice versa. This configuration allows the ends of the fourth conducting wires to protrude from third PCB 170, facilitating the soldering process.

It should be noted that, the above descriptions of FIGS. 12-17 are for illustration purposes and non-limiting. In some embodiments, wire grooves are unnecessary, and first wire grooves 1531 in FIG. 14 can be denoted as the first wires, second wire grooves 1541 in FIG. 15 can be denoted as the second wires, third wire grooves 161 in FIG. 16 can be denoted as the third wires, and fourth wire grooves 172 in FIG. 17 can be denoted as the fourth wires.

In some embodiments, the transmission cable assembly may include multiple traps fitted to transmission cable. An insulating component may be placed between every two adjacent traps. FIGS. 18-22 show various embodiments with such a transmission cable assembly. As shown in FIGS. 18-22, multiple traps 100 may fit on transmission cable 200 and serially connected along the axial axis (the longitudinal direction) of transmission cable 200. Between every two adjacent traps 100, there is an insulating component 300.

In some embodiments, each insulating component 300 has one or more mounting holes to mount traps 100. There is one insulating component 300 on each side of a trap 100. Multiple traps 100 are spaced apart along the longitudinal axis of transmission cable 200. Insulating components 300 isolate the adjacent traps 100 between which they are placed, preventing short circuits between the traps. Each trap 100 is fitted around the outer circumference of transmission cable 200.

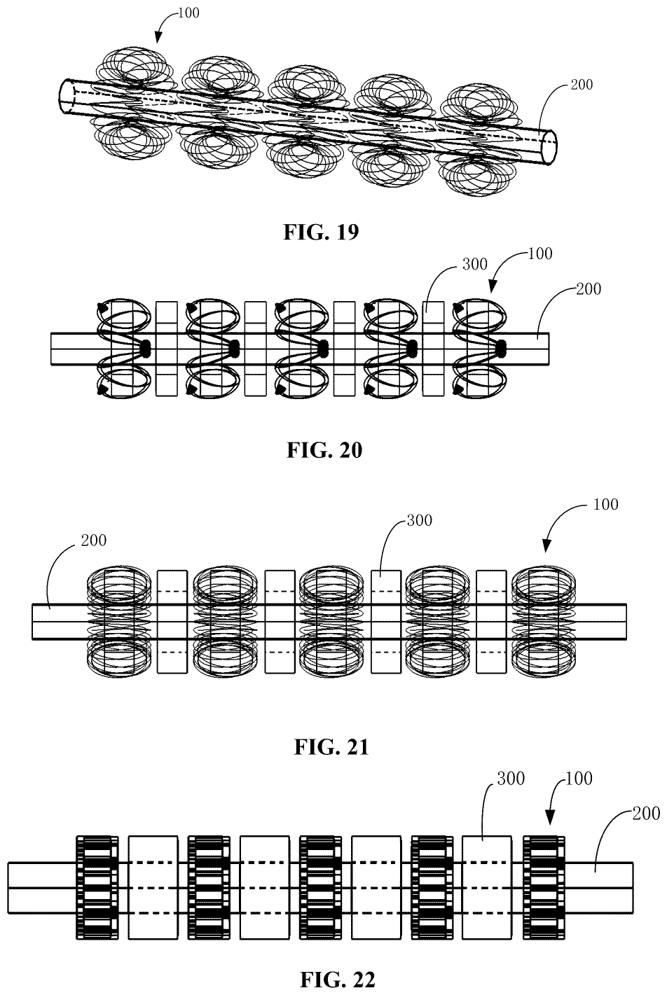

It is contemplated that any type of trap, including at least those embodiments described above, can be serially connected to form this trap assembly. For example, FIG. 18 is a schematic diagram showing a transmission cable assembly with multiple closed-loop spiral coil traps fitted on a transmission cable, according to embodiments of the present disclosure. FIG. 19 is a schematic diagram showing a transmission cable assembly with multiple open-loop spiral coil traps fitted on a transmission cable, according to embodiments of the present disclosure. FIG. 20 is a schematic diagram showing a transmission cable assembly with multiple closed-loop spiral coil traps wound around respective brackets fitted on a transmission cable, according to embodiments of the present disclosure. FIG. 21 is a schematic diagram showing a transmission cable assembly with multiple open-loop spiral coil traps wound around respective brackets fitted on a transmission cable, according to embodiments of the present disclosure. FIG. 22 is a schematic diagram showing a transmission cable assembly with multiple PCB traps fitted on a transmission cable, according to embodiments of the present disclosure.

The serial arrangement provides the transmission cable assembly with enhanced common-mode current suppression capabilities and results in low heat generation, and thus are suitable for different types of transmission cables. The serial trap assembly can be easily installed on and completely detached from any transmission cable without affecting any coil parameters, making it convenient for manufacturing and debugging. This also disperses the energy across multiple traps 100, reducing the heat generated by individual traps 100. Even if a specific trap is damaged, it will not affect the overall effectiveness of common-mode current suppression.

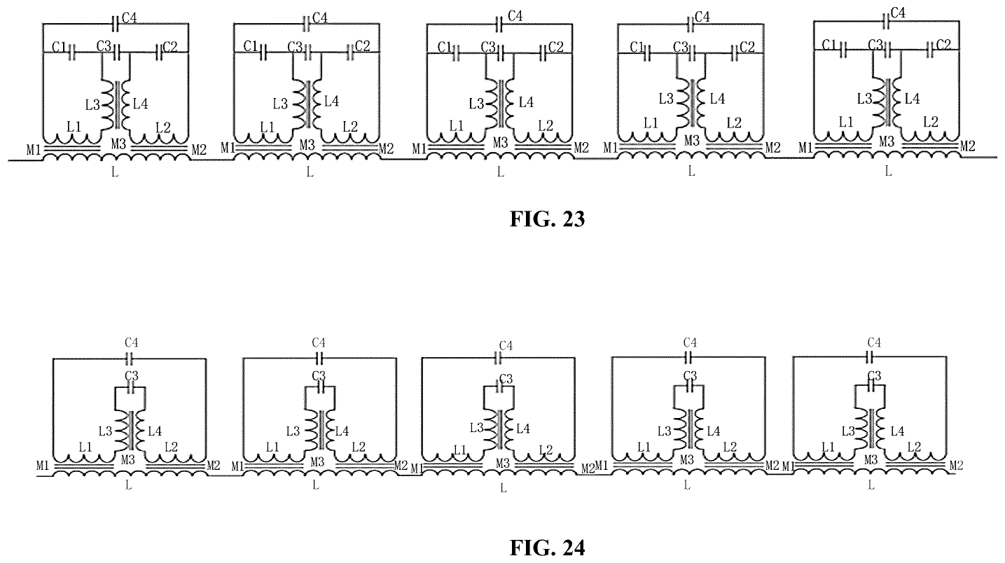

When multiple traps 100 are serially connected along the longitude axis of transmission cable 200, the traps are connected electrically in series. For example, FIG. 23 shows an equivalent circuit diagram of an exemplary transmission cable assembly having multiple closed-loop traps and FIG. 24 shows an equivalent circuit diagram of another exemplary trap assembly having multiple open-loop traps, according to embodiments of the present disclosure.

Some embodiments of the present disclosure may provide at least one trap used to suppress interference signals on a transmission cable. The at least one trap may be fitted on (e.g., detachably fitted on) the transmission cable. Each of the at least one trap may include a first coil and a second coil in the same winding direction, e.g., the clockwise direction, the anticlockwise direction. In some embodiments, the first coil and the second coil may circumferentially surround at least a portion of the transmission cable. In some embodiments, the transmission cable includes multiple portions along the longitude direction of the transmission cable. For example, the at least a portion of the transmission cable may include one portion of the multiple portions of the transmission cable. In some embodiments, there are multiple traps, and one trap is fitted onto each of at least one portion of the multiple portions of the transmission cable.

The first coil and the second coil may be open-loop coils or closed-loop coils. In some embodiments, when the first coil and the second coil are closed-loop coils, an end of the transmission cable may be inserted into a center through hole of the at least one trap, such that the at least one trap wraps around the transmission cable. When the first coil and the second coil are open-loop coils, the transmission cable may pass through gaps of the first coil and the second coil, such that the at least one trap wraps around the transmission cable.

In some embodiments, the first coil and the second coil may be spaced apart from each other or interleaved. The resonance may be formed by utilizing the distributed capacitances and inductances between the two coils. The values of the distributed capacitances and/or inductances may be adjusted by adjusting the spacing between the first coil and the second coil. When the common-mode current appears on the transmission cable, the energy enters the coils through coupling, and the current opposite to the direction of the common mode current is formed in the center of the coils, thereby suppressing the common-mode current. Because the at least one trap of the present disclosure is wrapped around the transmission cable, the at least one trap can be easily installed on and completely detached any transmission cable without affecting parameters of the transmission cable itself, therefore, the loss of the transmission cable (e.g., RF transmission cable) may not be additionally increased.

Besides, fitting the disclosed trap to the transmission cable without direct electrical connections improves maintainability. The disclosed trap skips the need to wind the transmission cable itself. Accordingly, the volume of the trap is no longer limited by the thickness of the transmission cable, allowing them to be smaller and lighter. The design can reduce the size and weight of the trap, while achieving the desired common-current reduction effects.

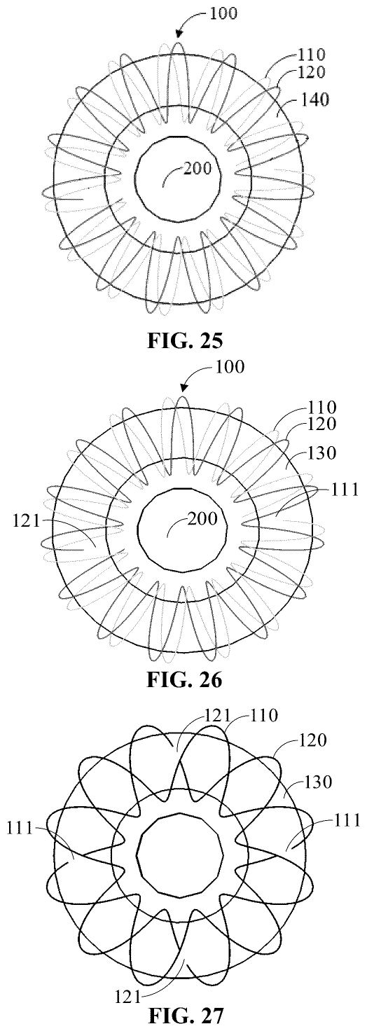

FIG. 25 is a schematic diagram of a trap fitted on a transmission cable according to embodiments of the present disclosure. FIG. 26 is a perspective diagram of a trap fitted on a transmission cable according to embodiments of the present disclosure. The transmission cable assemblies in FIGS. 25 and 26 include a single trap and will be described together. Trap 100 may be (detachably) fitted to transmission cable 200. Trap 100 wrap around transmission cable 200 in use. Trap 100 includes a first coil 110 and a second coil 120 made of conductive materials (e.g., metallic material). Trap 100 is prepared by: winding first coil 110 (or second coil 120) into an annulus and spiral coil. In some embodiments, the shape and/or size of first coil 110 and second coil 120 may be the same.

First coil 110 is an open-loop coil, that is, two ends of first coil 110 are separated by at least one first gap. Second coil 120 is an open-loop coil, that is, two ends of second coil 120 are separated by at least one second gap. The gaps of first coil 110 and second coil 120 are symmetrically arranged as shown in FIG. 26. In some other embodiments, the gaps of first coil 110 and second coil 120 may be set close to each other (e.g., as shown in FIG. 25). The tuning can be changed by adjusting the relative position of the gaps and/or the count of the gaps.

As shown in FIG. 26, first coil 110 includes a first gap 111, and second coil 120 includes a second gap 121. A count of the at least one first gap and/or a count of the at least one second gap may be non-limiting. In some embodiments, first coil 110 may have multiple first gaps, and/or second coil 120 may have multiple second gaps. The multiple first gaps (or the multiple second gaps) are alternately arranged on the first coil (or the second coil). FIG. 27 shows a trap with multiple gaps according to embodiments of the present disclosure. As shown in FIG. 27, two first gaps 111 are alternately arranged on first coil 110, and two second gaps 121 are alternately arranged on second coil 120. By arranging multiple gaps on first coil 110 and second coil 120 respectively, the tuning can be carried out by adjusting the count of gaps and/or the position of the gaps, so that the trap 100 is convenient for debugging.

In some embodiments, at least one first tuning capacitor (e.g., a lumped capacitor) may be set on first coil 110, and/or at least one second tuning capacitor (e.g., a lumped capacitor) may be set on second coil 120. In some embodiments, the at least one first tuning capacitor (or the at least one second tuning capacitor) may be located at least one gap of first coil 110 (or second coil 120). In some embodiments, when first coil 110 includes multiple first gaps, a tuning capacitor may be arranged at each individual first gap. When second coil 120 includes multiple second gaps, a tuning capacitor may be arranged at each individual second gap.

FIG. 28 shows a trap with tuning capacitors disposed on gaps according to embodiments of the present disclosure. As shown in FIG. 28, trap 100 includes a first lumped capacitor 112 and a second lumped capacitor 122. First lumped capacitor 112 may be connected to a first gap 111 of first coil 110, and second lumped capacitor 122 may be connected to a second gap 121 of second coil 120. In some embodiments, lumped capacitor 112 or 122 may include one or more capacitors. By arranging first lumped capacitor 112 on first coil 110 and second lumped capacitor 122 on second coil 120, the capacitance values of the lumped capacitors can be changed for tuning, so as to facilitate the debugging of trap 100.

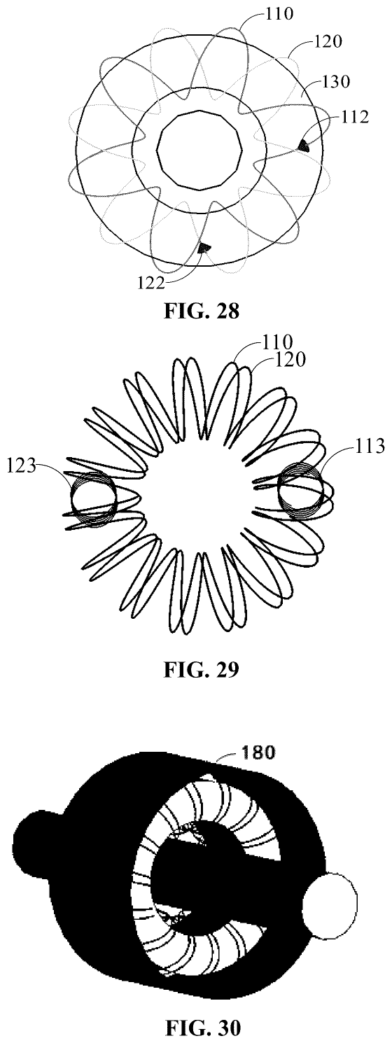

In some embodiments, first coil 110 may include at least one first twisted pair structure and/or second coil 120 may include at least one second twisted pair structure. One of the at least one first twisted pair structure and/or the at least one second twisted pair structure may extend along a longitudinal axis of the direction. FIG. 29 is a schematic diagram showing a trap with twisted pair structure, according to embodiments of the present disclosure. As shown in FIG. 29, first coil 110 may include a first twisted pair structure 113, and second coil 120 may include a second twisted pair structure 123. First coil 110 can extend from the end of its gap to form first twisted pair structure 113 that is intertwined with each other. Second coil 120 can extend from the end of its gap to form second twisted pair structure 123 that is intertwined with each other. The extension direction of first twisted pair structure 113 and second twisted pair structure 123 in FIG. 29 are parallel to the longitudinal axis of transmission cable 200. By adjusting the length, position, or direction of first twisted pair structure 113 and/or second twisted pair structure 123, the value of the distributed capacitance of trap 100 can be adjusted, facilitating the tuning of the trap 100.

It should be noted that when first coil 110 (or second coil 120) includes multiple gaps, a twisted pair structure may be disposed in each individual gap of the multiple gaps.

In some embodiments, at least one bracket may be used as a support frame to support trap 100. For example, trap 100 may be fixedly arranged on the at least one bracket. In some embodiments, the at least one bracket may be wrapped around the transmission cable. For example, the at least one bracket may be configured to allow the transmission cable to pass through the trap. In some embodiments, the at least one bracket may be made of insulating material. As shown in FIG. 25, bracket 140 is configured to support (e.g., fix) first coil 110 and second coil 120. Bracket 140 includes a through hole 141 in the center to allow transmission cable 200 to be inserted and pass through. First coil 110 and second coil 120 are wound around bracket 140, ensuring their stability on transmission cable 200. In order to protect first coil 110 and second coil 120, the gap between first coil 110 (or second coil 120) and bracket 140 may be filled with insulating material, or the parts where first coil 110 (or second coil 120) are in contact with transmission cable 200 may be filled with insulating material. In some other embodiments, a notch may also be arranged on bracket 140 for wrapping and/or fixing first coil 110 and second coil 120. In some other embodiments, first coil 110 and second coil 120 may be directly fixed on transmission cable 200 using curable insulating materials without arranging bracket 140.

In some embodiments, two first ends of first coil 110 may be fixed on bracket 140 by a gluing manner (e.g., a dispensing fixation manner), and two second ends of second coil 120 may be fixed on bracket 140 by a gluing manner (e.g., a dispensing fixation manner). For example, first coil 110 and second coil 120 are each provided with only one gap, and when first coil 110 (or second coil 120) is fixed to bracket 140, first coil 110 (or second coil 120) is first threaded on the bracket 140, and then the ends of the gap are respectively fixed with the bracket 140 using the gluing manner. When a plurality of gaps are arranged on first coil 110 (or second coil 120), the ends of each gap can be fixed with bracket 140 by the gluing manner. In some embodiments, a fixing hole may also be arranged on bracket 140, and first coil 110 and second coil 120 can be fixed in the fixing hole by fixing the ends of first coil 110 (or second coil 120).

In some embodiments, at least one shielding enclosure may be arranged to cover the trap, thereby reducing the influence of the magnetic field leaking from the trap on the radio frequency field. The at least one shielding enclosure may have an annular shape. An insulating material can be filled between the shielding enclosure and trap 100 for insulation and fixation. FIG. 30 is a schematic diagram showing a trap with a shielding enclosure according to embodiments of the present disclosure. As shown in FIG. 30, a shielding enclosure 180 covers trap 100.

In some embodiments, multiple traps may be detachably fitted onto the transmission cable. All of the multiple traps may be in series connection. Two adjacent traps may be isolated by an insulating medium, e.g., air, plastic, rubber, glass, ceramics, epoxy resin, etc. FIG. 31 is a schematic diagram showing a transmission cable assembly with multiple open-loop spiral coil traps wound around respective brackets fitted on a transmission cable, according to embodiments of the present disclosure. FIG. 32 shows an equivalent circuit diagram of the multiple traps in FIG. 31 according to embodiments of the present disclosure. As shown in FIG. 31 and FIG. 32, five traps 100 are detachably fitted onto transmission cable 200.

The serial arrangement provides enhanced common-mode current suppression capabilities and results in low heat generation, and thus are suitable for different types of transmission cables. The serial traps can be easily installed on and completely detached any transmission cable without affecting any coil parameters, making it convenient for manufacturing and debugging. This also disperses the energy (e.g., the common-mode current) across multiple traps, reducing the heat generated by an individual trap. Even if a specific trap is damaged, it will not affect the overall effectiveness of common-mode current suppression.

In some embodiments, similar to the trap (trap 1) including coils wound in opposite directions, the trap (trap 2) including coils wound in the same direction can also be fabricated using PCBs. The design principle of the PCBs for trap 2 may be analogous to the design principle of the PCBs for trap 1, with the distinction that the coils are wound in the same direction.

According to some embodiments of the present disclosure, a RF coil assembly system may be provided. The RF coil assembly may be used in a MRI system. The RF coil assembly may have an RF coil, a transmission cable and at least one trap. The transmission cable may be coupled to the RF coil. The at least one trap may be (detachably) fitted onto the transmission cable in order to form a resonant circuit. Each of the at least one trap may be the same as or similar to the trap described above.

According to some embodiments of the present disclosure, an MRI system may be provided. The MRI system may include at least one trap. Each of the at least one trap may be the same as or similar to the trap described above.

During the nuclear magnetic resonance scanning process, when a volume transmit coil emits high power, a relatively large common-mode current may be generated on a transmission cable of a receiving coil of an MRI device. To suppress the common-mode current, it is necessary to design traps on the transmission cable of the receiving coil. With technological advancements, a count of units in the receiving coil continues to increase, which leads to the transmission cable becoming increasingly thicker. Designing traps on the transmission cable will undoubtedly further increase the diameter of the transmission cable, posing many challenges for trap design.

In some embodiments, a plurality of types of traps may be used on the transmission cable to suppress the common-mode current.

The first type of trap is a cable trap, with the specific structure shown in FIG. 33. The cable trap winds a transmission cable 3310 into a spiral shape. The spiral transmission cable 3310 is provided with a winding inductance 3340 and is covered with a shielding cover 3320 on the outside. One end of the shielding cover 3320 is directly soldered to the transmission cable 3310, while the other end is connected to a tuning capacitor 3330. Because the cable trap typically has a large inductance, it can effectively suppress the common-mode current while generating minimal heat. However, the cable trap has several drawbacks, for example, its volume is typically large and weight is heavy, and it increases the transmission cable losses and impacts a total phase distance. Additionally, as the transmission cable becomes thicker, the diameter of the spiral windings also increases and the winding operability decreases.

Another type of trap is a floating trap. The floating trap does not need to be fixedly connected to the transmission cable and is detachable. It can be easily installed on any transmission cable without affecting any coil parameters. However, the floating trap typically has a small inductance and generates a significant amount of heat. Its performance to reduce the common-mode current relies on the size of its diameter, the larger the diameter, the better the performance. Therefore, in order to effectively suppress the common-mode current, the volume of the floating trap has to be large and thus the floating trap is inevitably heavy.

In order to take into account a suppression effect on the common-mode current and the miniaturization design requirements at the same time, some embodiments of the present disclosure propose a transmission cable assembly for MRI devices, which adopts a new type of miniaturized detachable trap. It has the advantages of small size, light weight, low heat generation, case of debugging, and ease of maintenance. The trap can enable the transmission cable to have a smaller maximum outer diameter and better bendability. At the same time, it can effectively suppress the common-mode current on the transmission cable, thereby reducing the impact on the local radio frequency field caused by the volume transmit coil. On the other hand, the transmission cable assembly provided in the present disclosure has a uniform overall structure and can be conveniently stored and positioned.

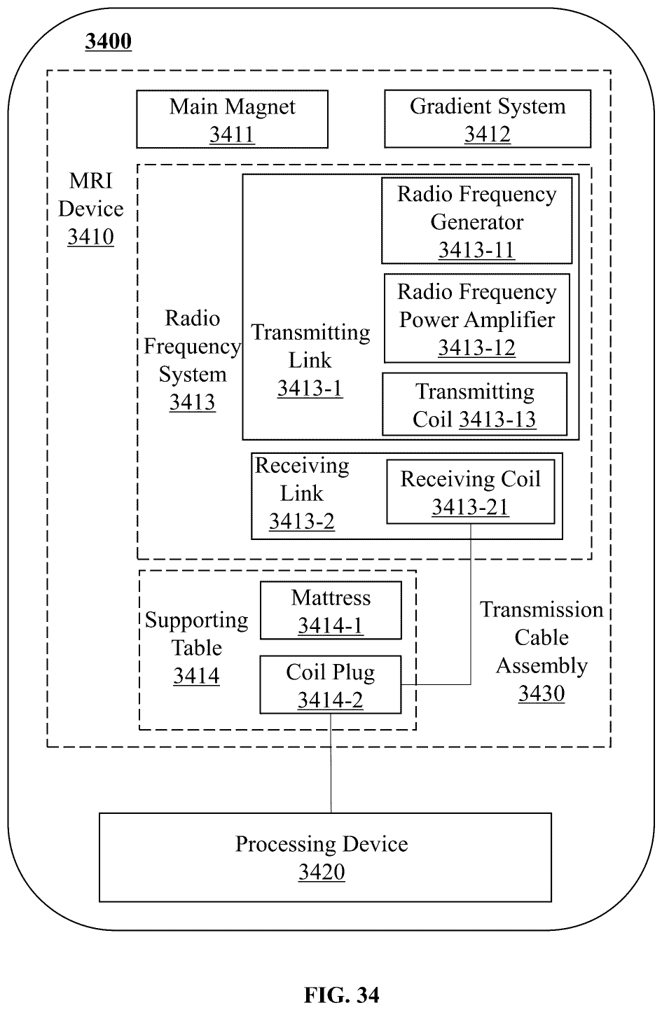

FIG. 34 is a schematic diagram showing an MRI system according to some embodiments of the present disclosure. As shown in FIG. 34, the MRI system 3400 includes an MRI device 3410 and a processing device 3420.

The MRI device 3410 may be used to perform magnetic resonance scans on an object. The object may include a biological object (e.g., human body, animal, etc.), a non-biological object (e.g., phantom), etc. In some embodiments, the object may include a specific part, an organ, and/or a tissue of a patient. For example, the object may include the head, chest, legs, etc., or any combination thereof, which is not limited herein.

The MRI device 3410 forms a scanning cavity capable of accommodating the object. In some embodiments, the MRI device 3410 may include a main magnet 3411, a gradient system 3412, a radio frequency system 3413, and a supporting table 3414.

The main magnet 3411 is a component that generates a magnetic field. For example, the main magnet 3411 may be an annular superconducting magnet installed inside an annular vacuum container. The superconducting magnet defines a cylindrical space surrounding the object and generates a constant main magnetic field. The main magnet 3411 may include superconducting coils and a cooling system. The superconducting coils are made of superconducting material, which has low resistance and high current carrying capacity. The cooling system is used to cool the superconducting coils to a low-temperature state, putting them into a superconducting state.

The gradient system 3412 is a system that provides three-dimensional spatial positioning for magnetic resonance imaging. The gradient system 3412 may include X, Y, Z three-channel gradient coils. The gradient system 3412 may further include a gradient controller, a digital/analog converter, a gradient amplifier, and a gradient cooling system, etc. The radio frequency system 3413 is a system that excites the object and collects magnetic resonance signals.

In some embodiments, the radio frequency system 3413 includes a transmitting link 3413-1 and a receiving link 3413-2. The transmitting link 3413-1 may transmit radio frequency pulses, causing the magnetized protons in the object's body to absorb energy and resonate. The receiving link 3413-2 may acquire the magnetic resonance signals.

In some embodiments, the transmitting link 3413-1 includes a radio frequency generator 3413-11, a radio frequency power amplifier 3413-12, and a transmitting coil 3413-13. The radio frequency generator 3413-11 is used to generate radio frequency signals of specific frequencies. The radio frequency power amplifier 3413-12 is used to amplify the radio frequency signals to drive the transmitting coil 3413-13 to transmit the radio frequency pulses to the object. In some embodiments, the transmitting coil 3413-13 includes a volume transmit coil.

In some embodiments, the receiving link 3413-2 includes a receiving coil 3413-21 (also referred to as an RF coil in the disclosure). For example, the receiving coil 3413-21 includes a local coil. The local coil is a high-sensitivity receiving coil close to a target part, used to capture the magnetic resonance signals of the target part. The local coil may be placed on the surface of the object's body and may enter the scanning cavity with the object. In some embodiments, multiple local coils may be used together and respectively receive the magnetic resonance signals generated during the magnetic resonance scan of the object. Each local coil includes multiple antenna units and amplifiers. The amplifiers amplify the weak magnetic resonance signals received by the antenna units.

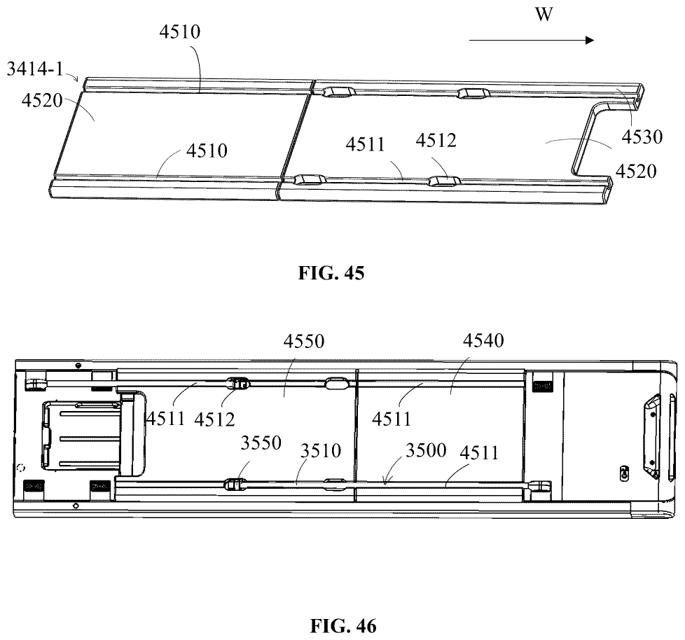

The supporting table 3414 may carry the object. In some embodiments, the supporting table 3414 is provided with a mattress 3414-1 and a coil plug 3414-2. In MRI scanning, the object needs to lie on the mattress 3414-1 of the supporting table 3414. More details about the mattress 3414-1 may be found in FIGS. 45-49 and their related descriptions.

The coil plug 3414-2 is an interface for connecting to the processing device 3420. In some embodiments, the receiving coil 3413-21 may be connected to the processing device 3420 through the coil plug 3414-2 and a transmission cable assembly 3430. The magnetic resonance signals captured by the receiving coil 3413-21 may be transmitted to the processing device 3420 through the transmission cable assembly 3430. The processing device 3420 may process the collected magnetic resonance signals. For example, it may perform filtering, amplification, analog-to-digital conversion, etc., on the collected magnetic resonance signals, and then perform magnetic resonance image reconstruction based on the processed magnetic resonance signals.

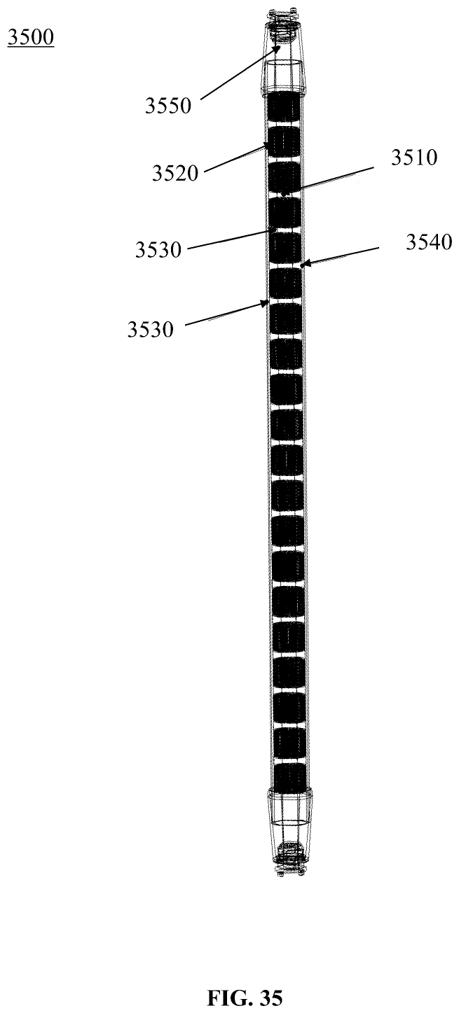

One end of the transmission cable assembly 3430 is connected to the receiving coil 3413-21, and the other end is inserted into the coil plug 3414-2, thereby establishing a connection between the receiving coil 3413-21 and the processing device 3420. In some embodiments, the transmission cable assembly 3430 may send control signals issued by the processing device 3420 to the receiving coil 3413-21 to control the receiving coil 3413-21. The transmission cable assembly 3430 may also receive the magnetic resonance signals or the processed magnetic resonance signals from the receiving coil 3413-21 and transmit the received signals to the processing device 3420. More content about the transmission cable assembly may be found in FIGS. 35-44 and their related descriptions.

FIG. 35 is a schematic diagram showing a transmission cable assembly according to some embodiments of the present disclosure.

As shown in FIG. 35, a transmission cable assembly 3500 includes a transmission cable 3510, a plurality of traps 3520, one or more insulating components 3530, and an outer sheath 3540. The outer sheath 3540 is sleeved over the transmission cable 3510; the plurality of traps 3520 are arranged between the outer sheath 3540 and the transmission cable 3510, and the plurality of traps 3520 are spaced apart along a longitudinal axis (also referred to as an axial direction) of the transmission cable 3510; each of one or more insulating components 3530 is placed between two adjacent traps of the plurality of traps 3520. The transmission cable assembly 3500 is an exemplary embodiment of the transmission cable assembly 3430 shown in FIG. 34.

The transmission cable 3510 is a cable used for transmitting signals. The transmission cable 3510 may include at least one cable. A count, function, etc., of the cable(s) included in the transmission cable 3510 may be set according to actual needs. The transmission cable 3510 may include a coaxial radio frequency cable, a symmetrical radio frequency cable, a spiral radio frequency cable, etc. In some embodiments, the transmission cable 3510 is electrically connected to an RF coil and configured to transmit MRI signals collected by the RF coil or processed MRI signals processed by the RF coil. In some embodiments, the RF coil is a receiving coil or a transmit-receive coil.

In some embodiments, the plurality of traps 3520 are provided on the transmission cable 3510, and the plurality of traps 3520 are spaced apart along the longitudinal axis of the transmission cable 3510. The plurality of traps 3520 may be equally spaced or unequally spaced along the longitudinal axis of the transmission cable 3510.

A trap 3520 includes a parallel resonant circuit (e.g., a circuit formed by parallel connection of one or more capacitors and one or more inductors). A resonant frequency of the parallel resonant circuit is equal to an interference frequency of a common-mode current that needs to be suppressed. When the trap 3520 is sleeved over the transmission cable 3510, a high impedance is applied to the transmission cable 3510 through coupling, thereby hindering the passage of the common-mode current through the transmission cable 3510 and reducing the impact on a local radio frequency field caused by a volume transmit coil.

In some embodiments, the plurality of traps 3520 may be connected in series along the longitudinal axis of the transmission cable 3510.

In some embodiments, the plurality of traps 3520 include a plurality of floating traps. The plurality of floating traps are connected to the transmission cable 3510 through mechanical engagement and their positions are adjustable. Connecting the plurality of floating traps in series to the transmission cable 3510 does not require cutting the transmission cable 3510, thus allowing the positions of the floating traps to be adjusted along the transmission cable 3510 through simple disassembly and reassembly operations.

In some embodiments, the plurality of traps 3520 are series-connected floating traps. This design is suitable for different types of transmission cables, and the floating traps can be easily installed and detached without affecting any coil parameters, facilitating manufacturing and debugging.

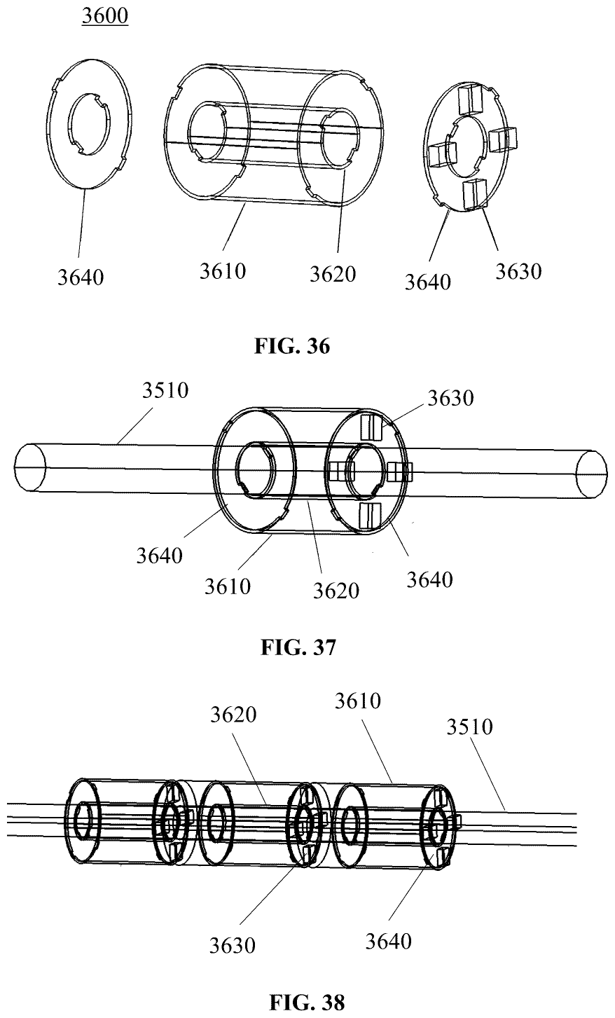

In some embodiments, the plurality of traps 3520 include a first trap. The first trap may include an inner sleeve, an outer sleeve, and one or more capacitors. More descriptions about the first trap may be found in FIGS. 36-40 and their related descriptions.

In some embodiments, the plurality of traps 3520 include a second trap. The second trap may include two annular spiral coils and one or more capacitors. More description about the second trap may be found in FIGS. 41, 1-32 and their related descriptions.

The insulating component 3530 is a structure used to isolate two adjacent traps 3520. The insulating component 3530 may be made of insulating material, such as plastic, ceramic, etc.

In some embodiments, the insulating component 3530 may be a ring-shaped structure, sleeved over the transmission cable 3510, and placed between two adjacent traps 3520. In some embodiments, the insulating component 3530 may be a ring-shaped sheet structure or a ring-shaped block structure, which may be set specifically according to actual needs.

In some embodiments, the insulating component 3530 may be placed between every two adjacent traps 3520.

In some embodiments, the one or more insulating components 3530 may be flexible insulating components, which are made of flexible insulating material. For example, the insulating component(s) may be made of felt, plastic, or other flexible materials.

In some embodiments, an outer diameter of each trap 3520 among the plurality of traps 3520 is the same as an outer diameter of each insulating component 3530 among the one or more insulating components 3530 such that the transmission cable assembly 3500 has a uniform outer diameter. The outer diameter of a component refers a diameter or radius of an outer contour of the component in a radial direction of the transmission cable 3510. Taking the trap in FIG. 8 as an example, its outer diameter may be a diameter of the shielding enclosure 400. Taking the trap in FIG. 36 as an example, its outer diameter may be a diameter of an outer sleeve 3610.

The outer sheath 3540 is a structure sleeved over the outside of the plurality of traps 3520 and the one or more insulating components 3530.

The outer sheath 3540 may be made of any feasible material. For example, the outer sheath 3540 may be made of plastic or rubber materials.

In some embodiments, the outer sheath 3540 may be a flexible outer sheath. For example, the outer sheath 3540 may be made of a flexible material such as leather, felt, a soft packaging material, etc. In some embodiments, the outer sheath 3540 and the one or more insulating components 3530 are made of different flexible materials. For example, the one or more insulating components 3530 are made of a flexible material with a relatively lighter weight, while the outer sheath 3540 is made of a flexible material with a relatively softer texture.

In some embodiments, the outer sheath 3540 may have a multi-layer structure. In some embodiments, the outer sheath 3540 may include a wrapping layer and a protective layer. The wrapping layer is located outside the protective layer. The protective layer is directly sleeved over the exterior of the plurality of traps 3520. In some embodiments, the protective layer may be made of insulating, fireproof, heat-insulating, or other materials. For example, the protective layer may be made of felt. In some embodiments, the wrapping layer may be made of the soft packaging material such as leather.

In some embodiments of the present disclosure, by arranging the plurality of traps on the transmission cable, the common-mode current can be effectively suppressed. By placing the insulating component between two adjacent traps, short circuits between the two adjacent traps can be prevented. At the same time, it also allows energy to be dispersed among the plurality of traps, reducing the heat generation of a single trap and ensuring the suppression effect on the common-mode current. Moreover, even if an individual trap is damaged, it will not affect the suppression effect on the common-mode current. By sleeving the outermost layer with the outer sheath, it can provide fire resistance and heat insulation; using a flexible material to make the outer sheath can effectively improve the touch feel. Meanwhile, by setting the outer diameter of the traps and the insulating component(s) to be the same, the transmission cable assembly can have a uniform, non-protruding structure and good bendability, facilitating storage and positioning.

In some embodiments, the transmission cable 3510 is divided into a first cable segment and a second cable segment, the second cable segment being further away from a central region of a volume transmit coil of the MRI device than the first cable segment. For example, the transmission cable 3510 may be divided along its longitudinal axis into one first cable segment and two second cable segments. The first cable segment is located between the two second cable segments and is closer to the central region of the volume transmit coil. A first portion of the plurality of traps 3520 are sleeved over the first cable segment, a second portion of the plurality of traps 3520 are sleeved over the second cable segment, and an arrangement density of the second portion of the plurality of traps 3520 is higher than that of the first portion of the plurality of traps 3520. The closer to the central region, the weaker a strength of the radio frequency field generated by the volume transmit coil. That is to say, the strength of the radio frequency field at the location of the second cable segment is greater than that at the first cable segment, and the common-mode current generated on the second cable segment is larger. Therefore, the traps may be arranged more densely on the second cable segment to better suppress the common-mode current.

The arrangement density refers to a sparsity level with which the traps 3520 are arranged on the transmission cable 3510. The arrangement density may be represented by a count of traps 3520 set on a preset length (e.g., 10 cm, etc.) of the transmission cable 3510. In some embodiments, the first portion of the plurality of traps 3520 may be uniformly spaced and sleeved over the first cable segment, the second portion of the plurality of traps 3520 may be uniformly spaced and sleeved over the second cable segment, and a spacing between adjacent two traps in the second portion is smaller than a spacing between adjacent two traps in the first portion.

In some embodiments, the first portion of the plurality of traps 3520 may be non-uniformly spaced and sleeved over the first cable segment, the second portion of the plurality of traps 3520 may be non-uniformly spaced and sleeved over the second cable segment, and a spacing between adjacent two traps 3520 closer to the central region of the volume transmit coil is larger.

In some embodiments of the present disclosure, the transmission cable is divided into a plurality of cable segments, and the arrangement density of the traps is targeted set according to the relative position of the cable segments to the central region of the volume transmit coil, ensuring the suppression effect on the common-mode current while saving equipment costs. Moreover, configuring corresponding transmission cables for different scanning scenarios can effectively improve the suppression effect on the common-mode current.

In some embodiments, the transmission cable 3510 is divided into a first cable segment and a second cable segment, the second cable segment being further away from a central region of a volume transmit coil of the MRI device than the first cable segment. The plurality of traps 3520 include first traps (e.g., a first trap 3600) and second traps (e.g., the second trap 100, a second trap 4100). Each first trap includes two sleeves (e.g., the outer sleeve 3610 and an inner sleeve 3620) and one or more first discrete capacitors. Each second trap includes two coils (e.g., the first coil 110 and the second coil 120) and one or more second discrete capacitors. The first traps are sleeved over the first cable segment, and the second traps are sleeved over the second cable segment. In some embodiments, a discrete capacitor is also referred to as a tunning capacitor. More details about the first trap may be found in FIGS. 36-40 and their related descriptions. More details about the second trap may be found in FIGS. 3-32, FIG. 41, and their related descriptions.

Relatively speaking, the first trap has a simple manufacturing process and low cost, but its equivalent inductance value is lower than that of the second trap. Therefore, it is more suitable for places where the radio frequency field is relatively weak. At locations close to the central region of the volume transmit coil (i.e., where the first cable segment is located), the radio frequency field is weaker, so the first traps are used; at locations far from the central region of the volume transmit coil (i.e., where the second cable segment is located), the radio frequency field is stronger, so the second traps are used. By mixing the use of the two types of traps, equipment costs can be saved while ensuring the suppression effect on the common-mode current.

In some embodiments, on the first cable segment, the closer to the central region of the volume transmit coil, the smaller the arrangement density of the first traps may be (i.e., the larger the spacing). On the second cable segment, the closer to the central region of the volume transmit coil, the smaller the arrangement density of the second traps may be (i.e., the larger the spacing). Such an arrangement can further improve the suppression effect on the common-mode current and reduce the equipment costs while combining the advantages of both types of traps.

FIG. 36 is a schematic diagram showing a first trap according to some embodiments of the present disclosure. FIG. 37 is a schematic diagram showing a first trap sleeved over a transmission cable according to some embodiments of the present disclosure. FIG. 38 is a schematic diagram showing a plurality of first traps sleeved over a transmission cable according to some embodiments of the present disclosure.

As shown in FIGS. 36, 37, and 38, the first trap 3600 includes an outer sleeve 3610, an inner sleeve 3620, and one or more first discrete capacitors 3630. The inner sleeve 3620 is sleeved over the transmission cable 3510; the outer sleeve 3610 is sleeved over the inner sleeve 3620; the first tuning capacitor(s) 3630 are arranged between the outer sleeve 3610 and the inner sleeve 3620, and one end of each first tuning capacitor 3630 is electrically connected to the inner sleeve 3620, and the other end is electrically connected to the outer sleeve 3610.

The outer sleeve 3610 and the inner sleeve 3620 are tubular structures that form the first trap 3600. Both the outer sleeve 3610 and the inner sleeve 3620 are hollow cylindrical structures with openings at both ends. A diameter of the outer sleeve 3610 is greater than a diameter of the inner sleeve 3620, and a length of the outer sleeve 3610 along the longitudinal axis of the transmission cable 3510 is equal to a length of the inner sleeve 3620 along the longitudinal axis of the transmission cable 3510.

In some embodiments, the outer sleeve 3610 is sleeved over the inner sleeve 3620, and a hollow space is formed between the outer sleeve 3610 and the inner sleeve 3620.

In some embodiments, the hollow space of the inner sleeve 3620 is used for threading the transmission cable 3510.

In some embodiments, the outer sleeve 3610 and the inner sleeve 3620 may be made of a conductive material. For example, the outer sleeve 3610 and the inner sleeve 3620 may be made of a metal material, such as iron, aluminum, copper, etc.

In some embodiments, the outer sleeve 3610 and the inner sleeve 3620 may be electrically connected to each other through the first tuning capacitor(s) 3630. Each first tuning capacitor 3630 is a capacitor connected to the outer sleeve 3610 and the inner sleeve 3620.

As shown in FIGS. 36 and 37, one end of a first tuning capacitor 3630 is electrically connected to the inner sleeve 3620, and the other end is electrically connected to the outer sleeve 3610. For example, a positive electrode of the first tuning capacitor 3630 may be connected to the inner sleeve 3620, and a negative electrode of the first tuning capacitor 3630 may be connected to the outer sleeve 3610. As another example, the negative electrode of the first tuning capacitor 3630 may be connected to the inner sleeve 3620, and the positive electrode of the first tuning capacitor 3630 may be connected to the outer sleeve 3610.

The first tuning capacitor 3630 may include a lumped capacitor. There may be a plurality of first discrete capacitors 3630. In some embodiments, there may be four first discrete capacitors 3630. The four first discrete capacitors 3630 may be equally spaced distributed in an annular area formed by an end face of the outer sleeve 3610 and an end face of the inner sleeve 3620. For example, an angle between every two adjacent first discrete capacitors 3630 of the four first discrete capacitors 3630 may be 90 degrees.

In some embodiments, the plurality of first discrete capacitors 3630 may be connected in series or in parallel. By adjusting the objects connected to the positive and negative electrodes of the first discrete capacitors 3630, a connection way between the plurality of first discrete capacitors 3630 may be adjusted. For example, when the positive electrode of each first tuning capacitor 3630 of the plurality of first discrete capacitors 3630 is connected to the inner sleeve 3620 and the negative electrode is connected to the outer sleeve 3610, then the plurality of first discrete capacitors 3630 are connected in parallel. When for every adjacent two first discrete capacitors 3630 among the plurality of first discrete capacitors 3630, the positive electrode of one first tuning capacitor 3630 is connected to the inner sleeve 3620 and the negative electrode of the one first tuning capacitor 3630 is connected to the outer sleeve 3610, and the negative electrode of the other first tuning capacitor 3630 is connected to the inner sleeve 3620 and the positive electrode of the other first tuning capacitor 3630 is connected to the outer sleeve 3610, then the plurality of first discrete capacitors 3630 are connected in series.

In some embodiments, the parts where the inner sleeve 3620 and the outer sleeve 3610 coincide with the transmission cable 3510 may serve as an equivalent inductance. The equivalent inductance and the first tuning capacitor(s) 3630 form an parallel resonant circuit. By adjusting a size of the equivalent inductance (e.g., by adjusting size parameters, metal materials, etc., of the inner sleeve 3620 and/or the outer sleeve 3610) and the first tuning capacitor(s) 3630, the circuit resonant frequency can be made consistent with the interference frequency of the common-mode current, thereby causing the parallel resonant circuit to exhibit high impedance, thus suppressing the passage of the common-mode current. The first trap 3600 may be tuned by adjusting the first tuning capacitor(s) 3630.

As shown in FIGS. 36, 37, and 38, in some embodiments, the first trap 3600 further includes a circuit board 3640 having a ring structure. An inner ring of the circuit board 3640 is connected to the inner sleeve 3620, an outer ring of the circuit board 3640 is connected to the outer sleeve 3610; and the one or more first discrete capacitors 3630 are disposed on the circuit board 3640 to connect the outer sleeve 3610 and the inner sleeve 3620.

In some embodiments, an inner diameter of the circuit board 3640 is the same as the diameter of the inner sleeve 3620, and an outer diameter of the circuit board 3640 is the same as the diameter of the outer sleeve 3610.

In some embodiments, the inner sleeve 3620 and the outer sleeve 3610 are the hollow cylindrical structures with openings at both ends. The circuit board 3640 may be provided at the ends of the inner sleeve 3620 and the outer sleeve 3610 on the same side.

In some embodiments, one end of the inner sleeve 3620 and one end of the outer sleeve 3610 may be fixed together with the circuit board 3640. For example, the end of the inner sleeve 3620 and the end of the outer sleeve 3610 may be fixed to the circuit board 3640 by snap connection, welding, etc.

In some embodiments, there may be one or two circuit boards 3640. For example, one circuit board 3640 may be disposed on one end of the hollow cylindrical structure formed by the inner sleeve 3620 and the outer sleeve 3610, or one circuit board 3640 may be disposed on each end of the hollow cylindrical structure formed by the inner sleeve 3620 and the outer sleeve 3610.

In some embodiments, a first tuning capacitor 3630 may be soldered onto the circuit board 3640. In some embodiments, circuits may be pre-set on the circuit board 3640 to achieve electrical connection between one end of the first tuning capacitor 3630 and the inner sleeve 3620, and electrical connection between the other end of the first tuning capacitor 3630 and the outer sleeve 3610. In some embodiments, the circuits may be pre-set on the circuit board 3640 to achieve series or parallel connection of a plurality of first discrete capacitors 3630.

In some embodiments of the present disclosure, using the metal material to make the outer sleeve and the inner sleeve can accelerate heat dissipation and make manufacturing simpler. The first trap can be tuned through the first tuning capacitor(s), giving the circuit advantages such as better selectivity, higher gain, and lower noise. By providing a ring-shaped circuit board, connecting the inner ring of the circuit board to one end of the inner sleeve, and connecting the outer ring of the circuit board to one end of the outer sleeve, the setting of the first tuning capacitor(s) can be made more convenient, and the overall structure of the first trap can be made more stable.

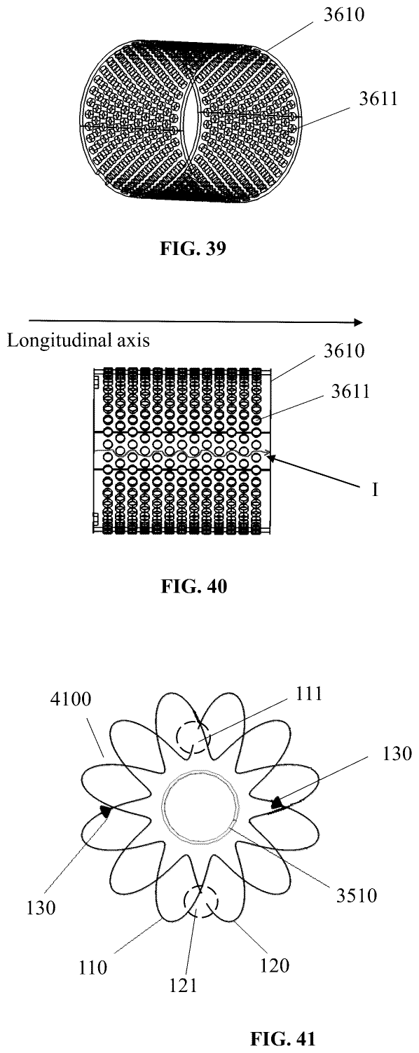

FIG. 39 is a schematic diagram showing an outer sleeve according to some embodiments of the present disclosure. FIG. 40 is a schematic diagram showing a side view of an outer sleeve according to some embodiments of the present disclosure.

As shown in FIGS. 39 and 40, a plurality of holes 3611 are arranged on the outer sleeve 3610.

The plurality of holes 3611 refer to holes opened on the outer sleeve 3610. The plurality of holes 3611 may be through holes or blind holes.

In some embodiments, the plurality of holes 3611 may be arranged along a radial direction of the outer sleeve 3610 but do not penetrate through the outer sleeve 3610, i.e., the plurality of holes 3611 are the blind holes. When the plurality of holes 3611 are arranged along the radial direction of the outer sleeve 3610, an axial direction of the plurality of holes 3611 is the same as the radial direction of the outer sleeve 3610.

In some embodiments, the plurality of holes 3611 may penetrate through the outer sleeve 3610 along its radial direction, i.e., the plurality of holes 3611 are the through holes.

In some embodiments of the present disclosure, by opening the plurality of holes on the outer sleeve, the effect of eddy currents on the outer sleeve can be effectively reduced. When the plurality of holes are set not to penetrate the outer sleeve (i.e., set as the blind holes), the heat dissipation area can be increased to enhance the heat dissipation effect of the outer sleeve. When the plurality of holes are set to penetrate the outer sleeve (i.e., set as the through holes), air convection can be utilized to enhance the heat dissipation effect of the outer sleeve.

As shown in FIGS. 39 and 40, in some embodiments, the plurality of holes 3611 are divided into multiple hole groups, each of which includes holes 3611 distributed along a circumferential direction of the outer sleeve 3610, the hole groups are spaced apart along a longitudinal axis of the outer sleeve 3610, and the holes in adjacent hole groups are arranged staggerly. Referring to FIG. 40, one hole group includes holes located in the same column in the side view.

In some embodiments, each of the multiple hole groups may be equally spaced along the longitudinal axis of the outer sleeve 3610. In some embodiments, cross-sections where geometric centers of different hole groups are located may be spaced apart along the longitudinal axis of the outer sleeve 3610, so that the multiple hole groups may be arranged along the longitudinal axis of the outer sleeve 3610. The distance between the cross-sections where the geometric centers of two adjacently arranged hole groups are located is the same, so that the multiple hole groups may be equally spaced along the longitudinal axis of the outer sleeve.

In some embodiments, the geometric centers of the plurality of holes 3611 in one hole group may be located on the same plane, which is a cross-section perpendicular to the longitudinal axis on the outer sleeve 3610.

In some embodiments, the plurality of holes 3611 in one hole group may be equally spaced along the circumferential direction of the outer sleeve 3610. For example, in one hole group, an included angle between lines connecting the geometric centers of every two adjacent holes 3611 and the geometric center (e.g., the center of the circle) of the cross-section where the geometric centers of the hole group is located is identical. At this time, the plurality of holes 3611 in the hole group are equally spaced.

In some embodiments, the holes in adjacent hole groups are arranged staggerly. This means: a line connecting the geometric center of any one hole 3611 of the plurality of holes 3611 in one hole group and the geometric center of any one hole 3611 of the plurality of holes 3611 in an adjacent hole group is not parallel to the longitudinal axis of the outer sleeve 3610.

It should be noted that the current direction (e.g., a direction of eddy current generated in the outer sleeve 3610 due to electromagnetic induction) is parallel to the longitudinal axis of the outer sleeve 3610. In some embodiments of the present disclosure, by opening a plurality of staggerly distributed holes on the outer sleeve, i.e., when adjacent two hole groups are staggerly arranged, the staggerly arranged holes will interrupt the current transmitted along the longitudinal axis direction of the outer sleeve, causing the current to pass through the gaps between the holes, which can thereby lengthen a path of the current on the outer sleeve (e.g., the current I as shown in FIG. 40) and effectively reduce the heat generation of the outer sleeve.

FIG. 41 is a schematic diagram showing a second trap according to some embodiments of the present disclosure.

The second trap 4100 shown in FIG. 41 is similar to the second trap 100 shown in FIG. 3, and the difference is that the second trap 4100 further includes gaps. As shown in FIG. 41, the second trap 4100 includes a first coil 110, a second coil 120, and one or more second discrete capacitors 130. Both ends of the first coil 110 are disconnected to form a first gap 111, and both ends of the second coil 120 are disconnected to form a second gap 121. Each of the one or more second discrete capacitors 130 is electrically connected to the first coil 110 or the second coil 120.

In some embodiments, the first coil 110 and the second coil 120 may be wound from insulated wires.

In some embodiments, the first coil 110 and the second coil 120 are constructed as annular spirals. In some embodiments, a size of an inner diameter of a ring formed by the first coil 110 and a size of an inner diameter of a ring formed by the second coil 120 may be set according to the diameter of the transmission cable 3510. For example, the larger the diameter of the transmission cable 3510, the larger the inner diameter of the ring formed by each of the first coil 110 and the second coil 120.

In some embodiments of the present disclosure, a distributed capacitance can be formed between the annular spiral first coil 110 and the annular spiral second coil 120. The distributed capacitance and the second tuning capacitor(s) 130 form a parallel resonant circuit with the equivalent inductances corresponding to the first coil 110 and the second coil 120, creating high impedance. When the common-mode current appears on the transmission cable 3510, energy enters the first coil 110 and the second coil 120 through coupling, forming a current in the center of the first coil 110 and the second coil 120 opposite to the direction of the common-mode current, thereby producing the suppression effect on the common-mode current. The second tuning capacitor(s) 130 and the gaps set on the first coil 110 and the second coil 120 can be used to adjust the resonant frequency of the coils, so that the resonant frequency of the coils reaches the required frequency (e.g., the interference frequency of the common-mode current). When the second trap 100 is sleeved over the transmission cable 3510, the high impedance is applied to the transmission cable 3510 through coupling, which can hinder the passage of the common-mode current through the transmission cable 3510. More description relating to the suppression of the common-mode current using the second trap can be found in elsewhere in this disclosure (e.g., FIG. 1-4 and the relevant descriptions).

In some embodiments, the first coil 110 and the second coil 120 have opposite helical directions or the same helical directions.

In some embodiments of the present disclosure, setting the first coil 110 and the second coil 120 to have opposite helical directions can cause, after the common-mode current is generated in the transmission cable 3510, the first coil 110 and the second coil 120 to generate magnetic fields in the same direction along the circumferential distribution. However, due to the opposite helical directions, the magnetic fields of the first coil 110 and the second coil 120 cancel each other out externally, reducing their impact on the local radio frequency field. Internally, their magnetic fields add up, creating a current along the axis of the transmission cable 3510 opposite to the direction of the common-mode current, which cancels out the common-mode current.

In some embodiments, the first coil 110 and the second coil 120 are arranged in an overlapping manner, and the first coil 110 and the second coil 120 form a first channel that allows the transmission cable 3510 to pass through.

In some embodiments of the present disclosure, by arranging the first coil 110 and the second coil 120 in an overlapping manner, a mutual inductance is formed between the first coil 110 and the second coil 120, thereby distributing the energy coupled from the transmission cable 3510 into the second trap 4100 into two current paths, reducing the heat generation of the trap 3520, and making the second trap 4100 smaller in volume and lighter in weight. Therefore, using the second trap 4100 with the above structure improves the effect of suppressing the common-mode current in the transmission cable 3510 while making the second trap 4100 smaller and lighter.

In some embodiments, arranging the first coil 110 and the second coil 120 in an overlapping manner and setting them to have the opposite helical directions may make the first coil 110 and the second coil 120 form a spiral interleaved structure. As shown in FIG. 18, in some embodiments, there may be a plurality of spiral interleaved structure spaced apart along the longitudinal axis of the transmission cable 3510. By arranging the plurality of spiral interleaved structures on the transmission cable 3510, the common-mode current can be effectively suppressed. In addition, the spiral interleaved structures are compatible with various types of transmission cables 3510. They are fully detachable, can be easily installed on any transmission cable 3510 without affecting coil parameters, and facilitate manufacturing and debugging.

In some embodiments, an insulating component (e.g., the insulating component 300) may be placed between two adjacent spiral interleaved structures to isolate them and prevent short circuits between the spiral interleaved structures. Doing so also allows energy to be dispersed among the spiral interleaved structures, reducing the heat generation of a single spiral interleaved structure. Moreover, even if an individual spiral interleaved structure is damaged, it will not affect the suppression effect on the common-mode current. Using the above structure has the advantage of reducing the heat generation of the single spiral interleaved structure and ensuring the suppression effect on the common-mode current. The spiral interleaved structure in the embodiment may be regarded as one trap.

A second tuning capacitor 130 is a capacitor connected to the first coil 110 or the second coil 120. The second tuning capacitor 130 may be used to adjust the resonant frequency of the first coil 110 or the second coil 120 to reach a required frequency (e.g., the interference frequency of the common-mode current).

In some embodiments, second discrete capacitors 130 may be set on the first coil 110 and the second coil 120, respectively. A count of the second discrete capacitors 130 set on the first coil 110 and the second coil 120 may be one, two, three, or even more.

In some embodiments, the transmission cable assembly further includes a bracket and an inductance tuning component. The bracket is sleeved over the transmission cable, the first coil and the second coil are wound around an outer surface of the bracket, and the bracket is provided with a mounting hole. The inductance tuning component is inserted into the mounting hole and configured to adjust a resonance frequency of the first coil and the second coil, wherein the resonance frequency of the first coil and the second coil is adjusted by adjusting an insertion depth of the inductance tuning component relative to the mounting hole.

For example, as shown in FIG. 9, the transmission cable assembly 200 further includes a bracket 140 sleeved over the transmission cable 200 and an inductance tuning component 190. The first coil 110 and the second coil 120 are wound around an outer surface of the bracket 140, and the bracket 140 is provided with a mounting hole (not shown in the figure). The inductance tuning component 190 is inserted into the mounting hole and configured to adjust a resonance frequency of the first coil 110 and the second coil 120, wherein the resonance frequency of the first coil 110 and the second coil 120 is adjusted by adjusting an insertion depth of the inductance tuning component 190 relative to the mounting hole.

The inductance tuning component 190 may be a threaded metallic rod. The mounting hole is a threaded slot matching the threaded metallic rod. More details about the bracket 140 may be found in the relevant descriptions above.

During coil winding, manual technique issues may cause variations in the tightness of the coils, leading to the resonant frequency of the coils not strictly matching the required resonant frequency. Therefore, the inductance tuning component is introduced to fine-tune the resonant frequency. In some embodiments of the present disclosure, by introducing the inductance tuning component, convenient and rapid adjustment of the resonant frequency can be achieved, ensuring that the resonant frequency is consistent with the interference frequency of the common-mode current and improving the suppression effect on the common-mode current.

In some embodiments, the first coil 110 and the second coil 120 are configured based on one or more coil parameters, the one or more coil parameters are determined by optimizing one or more initial coil parameters to achieve an optimization target, and the optimization target is related to a Q factor of the first coil 110 and the second coil 120.

In some embodiments, the coil parameter(s) may include one or more of parameters relating to the coil configuration, such as inner and outer diameters, a count of turns, a length, a capacitance value, etc.

The initial coil parameter(s) may be pre-set coil parameters. In some embodiments, the initial coil parameters may be set by a user based on experience. In some embodiments, when configuring the coil parameters for a certain MRI device in a scan, the suppression effect on the common-mode current of other magnetic resonance devices with the same model as the certain MRI device in historical scans of the same type as the scan may be analyzed, and the initial coil parameters may be determined based on the coil parameter values corresponding to historical scans with better suppression effects. The suppression effect on the common-mode current in a scan may be evaluated based on the quality of an image acquired by the scan.

In some embodiments, the optimization target may include maximizing the Q factor of the first coil 110 and the second coil 120. The Q factor refers to a quality factor of an inductor coil, which may be used to measure the performance of the first coil and the second coil.

In some embodiments, the process of optimizing the initial coil parameter(s) may be performed by a processing device. For example, the processing device may input the initial coil parameters into an optimization algorithm (such as a neural network, a genetic algorithm, etc.) and set the optimization target to maximize the Q factor of the coil. The optimization algorithm is used to optimize the initial coil parameter(s) to achieve the optimal Q factor, then the optimization is stopped, and the optimal solution (i.e., the coil parameter(s)) is obtained.

More details about the first coil 110, the second coil 120, and the second tuning capacitor 130 may be found in FIGS. 3-32 and their related descriptions.

In some embodiments of the present disclosure, using the optimization algorithm to determine the coil parameters can improve the accuracy of the coil parameters, thereby improving coil performance and the suppression effect on the common-mode current.

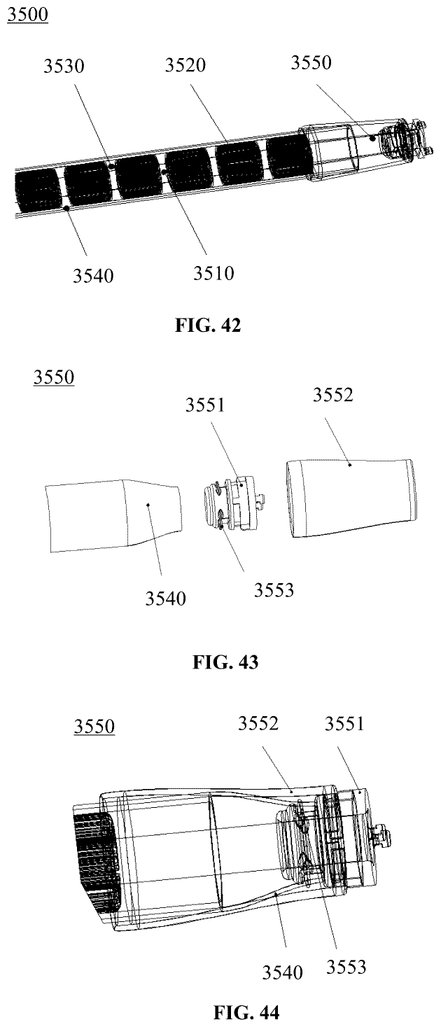

FIG. 42 is a schematic diagram showing a transmission cable assembly according to some embodiments of the present disclosure. FIG. 43 is a schematic diagram showing an internal structure of a connector according to some embodiments of the present disclosure. FIG. 44 is a schematic diagram showing an assembled connector according to some embodiments of the present disclosure.

As shown in FIGS. 42-44, the transmission cable assembly 3500 further includes a connector 3550. The connector 3550 includes a connecting component 3551 and a housing 3552. The connecting component 3551 is coupled to an end of the transmission cable 3510, and the housing 3552 is sleeved over the connecting component 3551.

The connector 3550 may allow the transmission cable 3510 to connect better to an external electrical connection structure. For example, the connector 3550 may allow the transmission cable 3510 to connect better to structures such as a coil plug.

The connecting component 3551 in the connector 3550 may allow the transmission cable 3510 to connect better to the external electrical connection structure. For example, by connecting the connecting component 3551 of the connector 3550 to the coil plug, the connector 3550 may be connected to the coil plug.

The connecting component 3551 may be in various structural forms. For example, the connecting component 3551 may be a cylindrical structure with snap-fit structures, hook structures, etc.

In some embodiments, the outer sheath 3540 may be sleeved over part or all of the connecting component 3551 and fixedly connected to the connecting component 3551 by the snap-fit structures, the hook structures, etc.

In some embodiments, the transmission cable 3510 includes a signal transmission line (not shown in the figure) and a tensile strength line (not shown in the figure). The connector 3550 includes a second channel (not shown in the figure) and a positioning line 3553 connected to the tensile strength line.

In some embodiments, the positioning line 3553 is connected to the tensile strength line, and the signal transmission line passes through the second channel. By providing the tensile strength line, the tensile strength of the transmission cable 3510 can be effectively enhanced.

The second channel allows the signal transmission line in the transmission cable 3510 to pass through. The connecting component 3551 may be a hollow cylindrical structure, and the second channel is provided in a hollow area of the connecting component 3551.

The positioning line 3553 is a structure used to fix the transmission cable 3510 to the connecting component 3551. By connecting the tensile strength line of the transmission cable 3510 to the positioning line 3553, the transmission cable 3510 may be fixed to the connecting component 3551. A connection way between the tensile strength line and the positioning line 3553 includes but is not limited to welding, winding connection, stitching connection, etc.

The housing 3552 is sleeved over an exterior of the connecting component 3551 and a part of the outer sheath 3540 connected to the connecting component 3551. In some embodiments, an inner diameter of the housing 3552 is greater than an outer diameter of the connecting component 3551 and greater than an outer diameter of the part of the outer sheath 3540 connected to the connecting component 3551.

In some embodiments, the housing 3552 may include two hollow cylindrical structures with different inner diameters. A hollow cylindrical structure with a smaller inner diameter is sleeved over the connecting component 3551, and a hollow cylindrical structure with a larger inner diameter is sleeved over the part of the outer sheath 3540 connected to the connecting component 3551.

In some embodiments, the housing 3552 may be assembled onto the connecting component 3551 in various ways to be sleeved over the exterior of the connecting component 3551 and the part of the outer sheath 3540 connected to the connecting component 3551. For example, the hollow cylindrical structure with the smaller inner diameter in the housing 3552 may be fixedly connected to the connecting component 3551 by any feasible means such as snap connection, threaded connection, riveting, etc.

In some embodiments of the present disclosure, by providing an end connector connected to the outer sheath, it is beneficial to connect the transmission cable to an external plug, forming a complete signal transmitting link. By connecting the line originally used for tensile strength (i.e., the tensile strength line) to the positioning line, the connection between the cable body and the end connector can be achieved without introducing other structures. By providing the housing sleeved over the connecting component 3551 and the part of the outer sheath 3540 connected to the connecting component 3551, the connection area between the connector and the outer sheath can be shielded, such as shielding the stitches between the tensile strength line and the positioning line, protecting the connection position between the connector and the outer sheath, and making the connection between the connector and the outer sheath more stable.

Some embodiments of the present disclosure also provide an MRI device, which comprises: an RF coil configured to detect MRI signals; a supporting table configured to support an object to be scanned; a coil plug disposed on the supporting table; and the transmission cable assembly configured to connect the RF coil and the coil plug. The transmission cable assembly comprises a transmission cable, a plurality of traps and one or more insulating components, wherein the plurality of traps are sleeved over the transmission cable and spaced apart along a longitudinal axis of the transmission cable, each of one or more insulating components is placed between two adjacent traps of the plurality of traps, and the transmission cable assembly assumes a uniform shape. In some embodiments, if the outer diameter of each trap is the same as the outer diameter of each insulating component or an outer diameter difference between each trap and each insulating component is smaller than a threshold (e.g., 0.5 centimeters, 1 centimeters), the transmission cable assembly is regarded as having a uniform shape. In some embodiments, if the transmission cable assembly does not have protruding structures and/or raised structures, the transmission cable assembly is regarded as having a uniform shape. Some embodiments of the present disclosure also provide a mattress for an MRI device. The mattress solves the storage problem of the transmission cable assembly by providing accommodation grooves and improves the experience of the object during scanning.

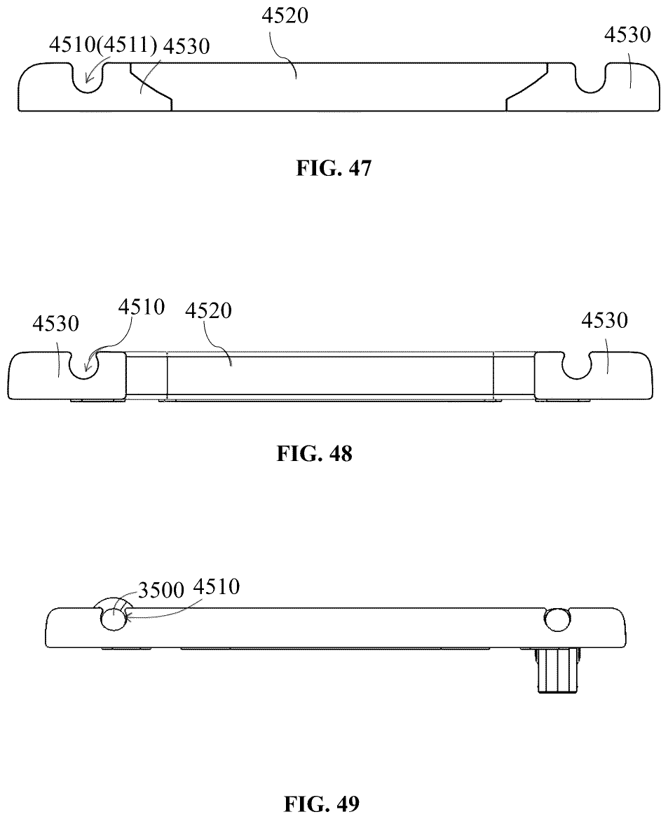

FIG. 45 is a schematic diagram showing a mattress of an MRI device according to some embodiments of the present disclosure. FIG. 46 is a schematic diagram showing a top view of a mattress of an MRI device according to some embodiments of the present disclosure. FIG. 47 is a schematic diagram showing a side view of a mattress of an MRI device according to some embodiments of the present disclosure. FIG. 48 is a schematic diagram showing a side view of a mattress of an MRI device according to some embodiments of the present disclosure. FIG. 49 is a schematic diagram showing a side view of a mattress of an MRI device with a transmission cable assembly installed according to some embodiments of the present disclosure.

As shown in FIGS. 45 and 46, the mattress 3414-1 is provided with one or more accommodation grooves 4510 extending along a longitudinal direction W of the mattress 3414-1. The longitudinal direction W of the mattress 3414-1 may also be called the length direction W, which is parallel to a direction in which the supporting table enters and leaves the scanning channel of the MRI device. The one or more accommodation grooves 4510 are configured to accommodate one or more transmission cable assembly (e.g., the transmission cable assembly 3500) of the MRI device.

In some embodiments, each accommodation groove of the one or more accommodation grooves 4510 includes one or more first grooves 4511 and one or more second grooves 4512 connected to each other.

A first groove 4511 is configured to accommodate a component with a smaller volume of the transmission cable assembly, such as the transmission cable (e.g., the transmission cable 3510) or the transmission cable wrapped by the outer sheath. A second groove 4512 is configured to accommodate a component with a larger volume of the transmission cable assembly, such as a connector (e.g., the connector 3550).

In some embodiments, along a width direction of the mattress 3414-1 (the width direction is perpendicular to the longitudinal direction W of the mattress 3414-1), a dimension (width) of each second groove of the one or more second grooves 4512 is greater than a dimension (width) of each first groove of the one or more first grooves 4511.

Thus, in MRI scanning, the transmission cable assembly can be placed in the accommodation groove 4510 without being draped over the object's body, avoiding affecting the object's experience. Moreover, the accommodation groove 4510 is divided into the first groove(s) 4511 and the second groove(s) 4512, and the width of each second groove 4512 is greater than the width of each first groove 4511. Therefore, the second groove(s) 4512 can accommodate larger volume structures in the transmission cable assembly, thereby expanding the application range of the accommodation groove 4510.

In some embodiments, each side of the mattress 3414-1 along the width direction is provided with an accommodation groove 4510, and each accommodating groove 4510 extends from one end to the other end of the mattress 3414-1 along the longitudinal direction. That is, a length of each accommodation groove 4510 along the longitudinal direction is equal to a length of the mattress 3414-1 along the longitudinal direction. Thus, the accommodation space of the accommodation grooves 4510 extending along the longitudinal direction is larger, the processing technology is simpler, and it is more convenient for storing the transmission cable assembly.

In other embodiments, an accommodation groove 4510 may extend along the width direction of the mattress 3414-1, and both ends of the accommodation groove 4510 may be spaced apart from the side walls of the mattress 3414-1, such that the transmission cable assembly will not fall out from the ends of the accommodation groove 4510 after being accommodated therein.

In some embodiments, the one or more second grooves 4512 include a plurality of second grooves, and adjacent second grooves are spaced apart along the longitudinal direction by one of the one or more first grooves. That is to say, the second grooves and the first groove(s) are arranged alternately, with one first groove placed between every two second grooves. Thus, the multiple second grooves 4512 may accommodate a plurality of spaced connectors 3550 on the transmission cable assembly.

Understandably, when the transmission cable assembly used with the mattress 3414-1 has more connectors 3550, such as three or four, a count of second grooves 4512 may also be adaptively increased.

In some embodiments, an opening of each second groove has an oblong shape or a rectangular shape. Thus, a shape of the second grooves 4512 is similar to a common shape of the connector 3550, allowing for a more fitting and stable installation of the connector 3550. In some embodiments, the opening of the second grooves 4512 may also be set to cylindrical, triangular, etc., as long as it matches the connector 3550.

In some embodiments, at least a portion of a cross-section of each first groove is semicircular. Referring to FIGS. 45 and 47, at least a portion of the cross-section of each first groove 4511 is semicircular. Since the transmission cable assembly is generally configured in a cylindrical shape, the groove wall of the semicircular first groove 4511 fits more adaptively with the transmission cable assembly.

In some embodiments, along the width direction of the mattress 3414-1, a width of an opening of a first groove 4511 is less than a diameter of the first groove 4511 itself. Since at least a portion of the first groove 4511 is semicircular, the diameter of the first groove 4511 is a diameter of the semicircle, and the width of the first groove 4511 is greatest at the diameter. The opening width being less than this diameter indicates that the edges of the groove extend inward toward each other, forming a narrowed structure of the opening. Therefore, when the transmission cable assembly is installed in the accommodation grooves 4510, the narrowed structure of the opening can restrict and secure the cable assembly, effectively preventing it from dislodging.

Since the width of the opening is less than the diameter, to facilitate the installation of the transmission cable assembly into the accommodation grooves 4510, the mattress 3414-1 may be set to include a supporting portion 4520 and two accommodation portions 4530, as shown in FIGS. 45, 47, and 48. The two accommodation portions 4530 are respectively connected to two sides of the supporting portion 4520 along the width direction of the mattress 3414-1. The one or more accommodation grooves 4510 include two accommodation grooves disposed on the two accommodation portions 4530, respectively.

An accommodation portion 4530 is made of high-resilience sponge material. Since the accommodation portion 4530 is made of the high-resilience sponge material, during the process of installing the transmission cable assembly into the accommodation groove 4510, the opening of the accommodation groove 4510 provided on the accommodation portion 4530 is able to deform, allowing the transmission cable assembly to be smoothly installed into the accommodation groove 4510, and allowing the accommodation portion 4530 to return to its initial state through its own deformation.

The supporting portion 4520 is made of memory foam material. Since the supporting portion 4520 is for the object to lie flat on, using softer memory foam material allows it to be compressed very flat (thin) under the weight pressure of the object, thus shortening the distance between the object and the MRI device and improving the imaging effect. The accommodation portions 4530 made of high-resilience sponge material can provide good limiting effect on the transmission cable assembly and further enhance the lying experience of the object. Some wider objects may lie on the accommodation portions 4530, and the accommodation portions 4530 can ensure the experience of objects of different body types.

In some embodiments, the mattress 3414-1 is divided into a plurality of segments along the longitudinal direction, and each segment among the plurality of segments is respectively provided with first grooves 4511 and/or second grooves 4512. Dividing the mattress 3414-1 into the plurality of segments allows each segment to be processed separately and then assembled, which can reduce process difficulty.

In some embodiments, the mattress 3414-1 is assembled by connecting the mattress segments along the longitudinal direction. As shown in FIG. 46, the mattress segments include one or more first mattress segments 4540 and one or more second mattress segments 4550. Only a portion of the one or more first grooves 4511 are arranged on the one or more first mattress segments 4540. The one or more second grooves 4512 and the remaining portion of the one or more first grooves 4511 are arranged on the one or more second mattress segments 4550. That is, only first groove(s) 4511 are arranged on the first mattress segment 4540, while both first groove(s) 4511 and second groove(s) 4512 are arranged on the second mattress segment 4550.

In some embodiments, the first mattress segment(s) 4540 and the second mattress segment(s) 4550 are connected and are separate entities. The first mattress segment(s) 4540 and the second mattress segment(s) 4550 may be processed separately and then assembled together, thereby reducing processing difficulty and cost.

The present disclosure also provides an MRI device, including the aforementioned mattress 3414-1 and a transmission cable assembly (e.g., the transmission cable assembly 3500). The transmission cable assembly is installed in an accommodation groove 4510 of the mattress 3414-1. The transmission cable assembly includes a transmission cable and a connector. The transmission cable is accommodated in a first groove 4511 of the accommodation groove 4510, and the connector is accommodated in a second groove 4512 of the accommodation groove 4510, making the installation of the transmission cable assembly more concise and aesthetic.

In some embodiments of the present disclosure, by opening an accommodation groove on the mattress to provide a placement space for the transmission cable assembly, the impact of the transmission cable assembly on the experience of the object is avoided. The structure of the accommodation groove is optimized, allowing both the transmission cable and the connector to be placed in the accommodation groove and not easily fall out.

The basic concepts have been described above, and it is apparent to those skilled in the art that the foregoing detailed disclosure serves only as an example and does not constitute a limitation of the present disclosure. While not expressly stated herein, a person skilled in the art may make various modifications, improvements, and amendments to this disclosure. Those types of modifications, improvements, and amendments are suggested in this disclosure, so those types of modifications, improvements, and amendments remain within the spirit and scope of the exemplary embodiments of this disclosure.

Also, the disclosure uses specific words to describe embodiments of the disclosure. Such as “an embodiment,” “an embodiment,” and/or “some embodiment” means a feature, structure, or characteristic associated with at least one embodiment of the present disclosure. Accordingly, it should be emphasized and noted that two or more references in this disclosure, at different locations, to “one embodiment,” or “an embodiment,” or “an alternative embodiment” in different places in this disclosure do not necessarily refer to the same embodiment. In addition, certain features, structures, or characteristics of one or more embodiments of the present disclosure may be suitably combined.

Furthermore, unless expressly stated in the claims, the order of the processing elements and sequences, the use of numerical letters, or the use of other names as described in this disclosure are not intended to qualify the order of the processes and methods of this disclosure. While some embodiments of the invention that are currently considered useful are discussed in the foregoing disclosure by way of various examples, it should be appreciated that such details serve only illustrative purposes, and that additional claims are not limited to the disclosed embodiments!, rather, the claims are intended to cover all amendments and equivalent combinations that are consistent with the substance and scope of the embodiments of this disclosure. For example, although the implementation of various components described above may be embodied in a hardware device, it may also be implemented as a software only solution, e.g., an installation on an existing server or mobile device.

Similarly, it should be noted that in order to simplify the presentation of the disclosure of this disclosure, and thereby aid in the understanding of one or more embodiments of the invention, the foregoing descriptions of embodiments of the disclosure sometimes group multiple features together in a single embodiment, accompanying drawings, or in a description thereof description thereof. However, this method of disclosure does not imply that more features are required for the objects of the present disclosure than are mentioned in the claims. Rather, claimed subject matter may lie in less than all features of a single foregoing disclosed embodiment.

Some embodiments use numbers to describe the number of components, attributes, and it should be understood that such numbers used in the description of an embodiment are modified in some examples by the modifiers “about,” “approximately,” or “substantially,” “approximately,” or “generally” is used in some examples. Unless otherwise noted, the terms “about,” “approximate,” or “approximately” indicates that a ±20% variation in the stated number is allowed. Correspondingly, in some embodiments, the numerical parameters used in the disclosure and claims are approximations, which can change depending on the desired characteristics of individual embodiments. In some embodiments, the numerical parameters should take into account the specified number of valid digits and employ general place-keeping. While the numerical domains and parameters used to confirm the breadth of their ranges in some embodiments of this disclosure are approximations, in specific embodiments such values are set to be as precise as practicable.

For each of the patents, patent applications, patent application disclosures, and other materials cited in this disclosure, such as articles, books, disclosure sheets, publications, documents, and the like, are hereby incorporated by reference in their entirety into this disclosure. Application history documents that are inconsistent with or conflict with the contents of this disclosure are excluded, as are documents (currently or hereafter appended to this disclosure) that limit the broadest scope of the claims of this disclosure. It should be noted that in the event of any inconsistency or conflict between the descriptions, definitions, and/or use of terms in the materials appended to this disclosure and those set forth herein, the descriptions, definitions, and/or use of terms in this disclosure shall control. use shall prevail.

Finally, it should be understood that the embodiments described in this disclosure are only used to illustrate the principles of the embodiments of this disclosure. Other deformations may also fall within the scope of this disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A transmission cable assembly for a radio frequency (RF) coil, comprising:
a transmission cable electrically connected to the RF coil;
an outer sheath sleeved over the transmission cable;
a plurality of traps and one or more insulating components arranged between the transmission cable and the outer sheath, wherein:
the plurality of traps are sleeved over the transmission cable and spaced apart along a longitudinal axis of the transmission cable,
each of one or more insulating components is placed between two adjacent traps of the plurality of traps.

2. The transmission cable assembly of claim 1, wherein the outer sheath is made of a flexible material.

3. The transmission cable assembly of claim 1, wherein the one or more insulating components are made of a flexible material.

4. The transmission cable assembly of claim 1, wherein an outer diameter of each trap is the same as an outer diameter of each insulating component such that the transmission cable assembly has a uniform outer diameter.

5. The transmission cable assembly of claim 1, wherein the plurality of traps comprise
a first trap, and the first trap comprises:
an inner sleeve sleeved over the transmission cable;
an outer sleeve sleeved over the inner sleeve; and
one or more first discrete capacitors electrically connected between the inner sleeve and the outer sleeve.

6. The transmission cable assembly of claim 5, wherein
the first trap further comprises a circuit board having a ring structure,
an inner ring of the circuit board is connected to the inner sleeve,
an outer ring of the circuit board is connected to the outer sleeve; and
the one or more first discrete capacitors are disposed on the circuit board.

7. The transmission cable assembly of claim 4, wherein a plurality of holes are arranged on the outer sleeve,
the plurality of holes are divided into a plurality of hole groups, each of which comprises holes distributed along a circumferential direction of the outer sleeve,
the hole groups are spaced apart along a longitudinal axis of the outer sleeve, and
the holes in adjacent hole groups are arranged staggerly.

8. The transmission cable assembly of claim 1, wherein the plurality of traps comprise
a second trap comprising:
a first coil, both ends of the first coil being disconnected to form a first gap;
a second coil, both ends of the second coil being disconnected to form a second gap;
one or more second discrete capacitors, each of which is electrically connected to the first coil or the second coil.

9. The transmission cable assembly of claim 8, further comprising:
a bracket sleeved over the transmission cable, wherein the first coil and the second coil are wound around an outer surface of the bracket, and the bracket is provided with a mounting hole; and
an inductance tuning component inserted into the mounting hole and configured to adjust a resonance frequency of the first coil and the second coil, wherein the resonance frequency of the first coil and the second coil is adjusted by adjusting an insertion depth of the inductance tuning component relative to the mounting hole.

10. The transmission cable assembly of claim 8, wherein the first coil and the second coil are configured based on one or more coil parameters, the one or more coil parameters are determined by optimizing one or more initial coil parameters to achieve an optimization target, the optimization target is related to a Q factor of the first coil and the second coil.

11. The transmission cable assembly of claim 1, further comprising a connector, wherein the connector comprises:
a connecting component coupled to an end of the transmission cable; and
a housing sleeved over the connecting component.

12. The transmission cable assembly of claim 11, wherein:
the transmission cable comprises a signal transmission line and a tensile strength line;
the connecting component forms a second channel for the signal transmission line and the tensile strength line to pass through, and
the connecting component comprises a positioning line connected to the tensile strength line.

13. The transmission cable assembly of claim 1, wherein
the transmission cable is divided into a first cable segment and a second cable segment, the second cable segment being further away from a central region of a volume transmit coil of a magnetic resonance imaging (MRI) device than the first cable segment,
a first portion of the plurality of traps are sleeved over the first cable segment,
a second portion of the plurality of traps are sleeved over the second cable segment, and
an arrangement density of the second portion of the plurality of traps is higher than that of the first portion of the plurality of traps.

14. The transmission cable assembly of claim 1, wherein
the transmission cable is divided into a first cable segment and a second cable segment, the second cable segment being further away from a central region of a volume transmit coil of an MRI device than the first cable segment,
the plurality of traps comprise first traps and second traps, each first trap comprising two sleeves and one or more first discrete capacitors, each second trap comprising two coils and one or more second discrete capacitors,
the first traps are sleeved over the first cable segment, and
the second traps are sleeved over the second cable segment.

15. A magnetic resonance imaging (MRI) device, comprising:
a radio frequency (RF) coil configured to detect MRI signals;
a supporting table configured to support an object to be scanned;
a coil plug disposed on the supporting table; and
a transmission cable assembly connect the RF coil and the coil plug, the transmission cable assembly comprising a transmission cable, a plurality of traps and one or more insulating components, wherein the plurality of traps are sleeved over the transmission cable and spaced apart along a longitudinal axis of the transmission cable, each of one or more insulating components is placed between two adjacent traps of the plurality of traps, and the transmission cable assembly assumes a uniform shape.

16. The MRI device of claim 15, wherein the MRI device further includes a mattress
the mattress is provided with one or more accommodation grooves extending along a longitudinal direction of the mattress,
the one or more accommodation grooves are configured to accommodate the transmission cable assembly,
each accommodation groove comprises one or more first grooves and one or more second grooves connected to each other, and
along a width direction of the mattress, a dimension of each second groove is greater than a dimension of each first groove.

17. The MRI device of claim 16, wherein the one or more second grooves comprise a plurality of second grooves, and adjacent second grooves are spaced apart along the longitudinal direction by one of the one or more first grooves.

18. The MRI device of claim 16, wherein:
an opening of each second groove has an oblong shape or a rectangular shape, and
at least a portion of a cross-section of each first groove is semicircular.

19. The MRI device of claim 16, wherein:
the mattress comprises a supporting portion and two accommodation portions,
the two accommodation portions are respectively connected to two sides of the supporting portion along the width direction of the mattress, and
the one or more accommodation grooves comprise two accommodation grooves disposed on the two accommodation portions, respectively.

20. The MRI device of claim 16, wherein:
the mattress is assembled by connecting a plurality of mattress segments along the length direction of the mattress,
the mattress segments comprise one or more first mattress segments and one or more second mattress segments,
only a portion of the one or more first grooves are arranged on the one or more first mattress segments,
the one or more second grooves and the remaining portion of the one or more first grooves are arranged on the one or more second mattress segments.
